(19) United States
(12) Patent Application Publication
(10) Pub. No.: US 2024/0066788 A1
(43) Pub. Date: Feb. 29, 2024

(54) METHOD OF PRODUCING NANOSCALE HOT EMBOSSED PATTERNS

(71) Applicant: McMaster University, Hamilton (CA)

(72) Inventors: Ponnambalam Selvaganapathy, Dundas (CA); Shady Abosree, Hamilton (CA)

(21) Appl. No.: 18/280,038

(22) PCT Filed: Mar. 4, 2022
(86) PCT No.: PCT/CA2022/050314

§ 371 Date: Sep. 1, 2023

Related U.S. Application Data
(60) Provisional application No. 63/200,412, filed on Mar. 5, 2021.

(51) Int. Cl. B29C 59/00; B29C 59/16; B29C 61/06

(52) U.S. Cl. CPC B29C 59/005; B29C 59/16; B29C 61/06; B29C 2059/023

(57) ABSTRACT

A method of producing nanoscale features on a pre-stressed polymer film is described herein. The method includes: imprinting the pre-stressed polymer film with a nanoscale or microscale pattern; constraining the pre-stressed polymer film in a first direction with a first constraint; shrinking the pre-stressed polymer film in a second direction with a first heat treatment process; releasing the first uniaxial constraint; constraining the pre-stressed polymer film in a third direction with a second constraint, the third direction being different than the first direction; shrinking the pre-stressed polymer film in a fourth direction with a second heat treatment process; and releasing the second constraint to produce the nanoscale features on the pre-stressed polymer film.

### CROSS-REFERENCE

This application claims the benefit of U.S. Provisional Patent Application No. 63/200,412 titled METHODS OF PRODUCING NANOSCALE HOT EMBOSSED PATTERNS, filed on Mar. 5, 2021, the entire contents of which are hereby incorporated by reference herein.

### TECHNICAL FIELD

This disclosure relates generally to methods of producing embossed patterns, and more specifically, to methods of producing nanoscale hot embossed patterns by constraining the thermally activated shrinkage of a shrinkable polymer film.

### BACKGROUND

Nanofabrication and the precise reproduction of features at the scale below 100 nm is crucial for a number of industrially relevant applications including semiconductor and IC fabrication, nanoelectromechanical systems (NEMS) as well as textured surfaces for biomedical applications. Nanolithography, which is associated with the nanofabrication, is a process of imprinting or fabrication of nanoscale patterns or features on a substrate [1]. One of the nanolithography techniques that has emerged over the last few decades is nanoimprint lithography (NIL) [2-4]. NIL has the ability to produce nano patterns of high density and high resolution at low cost and high throughput. However, it is a replication or duplication process that transfers the features on a master mold into a polymeric material fixed on another substrate [5]. The master molds are generally fabricated using focused ion beam lithography or electron beam lithography which are time-consuming and expensive processes [6-8]. Thus, the most expensive step in a complete NIL fabrication process is the fabrication of the master mold [9-11]. Since NIL is a 1:1 replication process, the resolution of the fabricated patterns depends on the resolution of the master mold. This will increase the complexity of master fabrication for nanoscale patterns (sub-100 nm). Moreover, if different patterns or different dimensions are required, new master molds have to be fabricated for each new pattern or size. Thus, developing a process that can create patterns with different dimensions from the same master mold can be helpful in reducing the time and cost required for new master molds.

One interesting approach to produce miniaturized patterns from larger original patterns is using shape memory polymers (SMP). SMPs are formed of randomly oriented polymer chains that can be stretched and fixed in the new stretched form [12, 13]. They are responsive to external stimuli that can be triggered by, for example, heating above the glass transition temperature (Tg) as in the heat shrinkable polymer films [14-16]. When an external stimulus is applied, shape recovery of the SMP takes place by relaxing the internal stresses where the polymer reflows and tends to recover to its original shape. By patterning the shrinkable films, these patterns also can be miniaturized when the entire film is triggered by the external stimulus and shrinks.

Thermal nanoimprint lithography (thermal-NIL) (which also known as hot embossing) has been used to pattern the pre-stressed films in order to miniaturize the features size after shrinking. A master mold which has relief structures is pressed against the polymer film to transfer the patterns by applying pressure and heating. However, the direct shrinking of embossed pre-stressed films fails to preserve the topographical features after shrinking [17, 18]. The reflow of material when the stress is relieved, causes reduction in pattern height and reduces the fidelity of the patterns. The reflow of material caused by the shape memory effect results in complete elimination of the imprinted patterns especially at the scale of a few hundred nanometers and below. An alternative approach where reactive ion etching (RIE) is used to embed the topographical features instead of hot embossing can preserve patterns as material is physically removed [19]. Using RIE, the patterned area is physically removed, thus the polymer does not return to the original shape after shrinking and finally the height of pattern increases. The features dimensions achievable after miniaturization are limited to few microns [19, 20] and in recent work to sub-micron [21]. However, this method is not suitable for sub 500 nm resolution features due to the rough surface generated from RIE process.

Accordingly, there is a need for new methods of producing embossed patterns.

### SUMMARY

In accordance with a broad aspect, a method of producing nanoscale features on a pre-stressed polymer film is provided. The method includes imprinting the pre-stressed polymer film with a nanoscale or microscale pattern; constraining the pre-stressed polymer film in a first direction with a first constraint; shrinking the pre-stressed polymer film in a second direction with a first heat treatment process; releasing the first uniaxial constraint; constraining the pre-stressed polymer film in the third direction with a second constraint, the third direction being different than the first direction; shrinking the pre-stressed polymer film in a fourth direction with a second heat treatment process; and releasing the second constraint to produce the nanoscale features on the pre-stressed polymer film.

In at least one embodiment, a temperature of the first heat treatment process is controlled to achieve final shrink dimensions between 100% and 30% of original dimensions of the pre-stressed polymer film.

In at least one embodiment, the first heat treatment process is conducted at a first temperature and the second heat treatment process is conducted at a second temperature, the first temperature being different than the second temperature.

In at least one embodiment, the first constraint is mechanical clamp, adhesive bonding or an electromagnetic means.

In at least one embodiment, the pre-stressed polymer film is a thermoplastic material such as polystyrene, polypropylene, polyester, polycarbonate, or elastomeric material such as polydimethylsiloxane and polyurethane.

In at least one embodiment, a shrinkage gradient is achieved by controlling the placement of the first constraint or controlling a magnitude of the first constraint relative to a location of the pattern.

In at least one embodiment, the pre-stressed polymer film is imprinted at a temperature between 110° C. and 140° C. using a force in a range of about 1000 N to about 10,000 N.

In at least one embodiment, the first heat treatment process is performed for a first duration and the second heat treatment process is performed for a second duration.

In at least one embodiment, the first heat treatment process is applied to obtain partial shrinkage of the nanoscale or microscale pattern to achieve a tunable degree of miniaturization.

In at least one embodiment, the second direction is orthogonal to the first direction.

In at least one embodiment, the fourth direction is orthogonal to the third direction.

In at least one embodiment, the second direction and the third direction are a same direction.

In at least one embodiment, the third direction and the first direction differ by an angle, the angle being less than about 90 degrees.

In at least one embodiment, the method also includes constraining the pre-stressed polymer film in a fifth direction with a third constraint; shrinking the pre-stressed polymer film in a sixth direction with a third heat treatment process, the sixth direction being orthogonal to the fifth direction; and releasing the third constraint to produce the nanoscale features on the pre-stressed polymer film.

In at least one embodiment, the imprinted pattern is a two-dimensional pattern.

In at least one embodiment, the imprinted pattern is a three-dimensional pattern.

In at least one embodiment, imprinting the prestressed polymer film includes imprinting the prestressed polymer film using xurography or laser machining lithography.

In at least one embodiment, the first constraint is a uniaxial constraint.

In at least one embodiment, the second constraint is a uniaxial constraint.

In accordance with another broad aspect, a method of producing nanoscale features on a pre-stressed polymer film is described herein. The method includes iteratively repeating any method of producing nanoscale features on a pre-stressed polymer film that is described herein.

These and other features and advantages of the present application will become apparent from the following detailed description taken together with the accompanying drawings. It should be understood, however, that the detailed description and the specific examples, while indicating preferred embodiments of the application, are given by way of illustration only, since various changes and modifications within the spirit and scope of the application will become apparent to those skilled in the art from this detailed description.

### BRIEF DESCRIPTION OF THE DRAWINGS

For a better understanding of the various embodiments described herein, and to show more clearly how these various embodiments may be carried into effect, reference will be made, by way of example, to the accompanying drawings which show at least one example embodiment, and which are now described. The drawings are not intended to limit the scope of the teachings described herein.

FIG. 1A shows a schematic illustration of the miniaturization process of hot embossed patterns on heat shrinkable polymer films by applying directional constrains during thermal shrinking, according to at least one embodiment described herein.

FIG. 1B shows a block diagram of a method of producing nanoscale features on a pre-stressed polymer film is described herein, according to at least one embodiment described herein.

FIG. 2A shows an atomic force microscopy (AFM) image of an imprinted pattern by hot embossing and the generated patterns.

FIG. 2C shows an AFM image of an imprinted pattern by hot embossing and the generated patterns after shrinking by applying constraints.

FIG. 2C shows an AFM image of an imprinted pattern by hot embossing and the generated patterns without applying constraints.

FIG. 2D shows corresponding height profile of the imprinted pattern by hot embossing of FIG. 2A.

FIG. 2E shows corresponding height profile of the imprinted pattern by hot embossing of FIG. 2B.

FIG. 2F shows corresponding height profile of the imprinted pattern by hot embossing of FIG. 2C.

FIG. 3A shows an SEM image of a hot embossed line-space pattern with initial dimensions of 750 nm.

FIG. 3B shows an SEM image of a shrunk pattern with initial dimensions of 750 nm.

FIG. 3C shows an inclined view of an SEM image of the shrunk pattern of FIG. 3B.

FIG. 3D shows an SEM image of a hot embossed line-space pattern with initial dimensions of 300 nm.

FIG. 3E shows an SEM image of a shrunk pattern with initial dimensions of 300 nm.

FIG. 3F shows an inclined view of an SEM image of the shrunk pattern of FIG. 3E.

FIG. 3G shows an SEM image of a hot embossed line-space pattern with initial dimensions of 150 nm.

FIG. 3H shows an SEM image of a shrunk pattern with initial dimensions of 150 nm.

FIG. 3I shows an inclined view of an SEM image of the shrunk pattern of FIG. 3H.

FIG. 4A shows an SEM images of a hot embossed hole array pattern with initial dimensions of 300 nm.

FIG. 4B shows an SEM image of a shrunk hole array pattern with initial dimensions of 300 nm.

FIG. 4C shows an inclined view of an SEM image of the shrunk hole array pattern of FIG. 4B.

FIG. 4D shows an SEM image of a hot embossed hole array pattern with initial dimensions of 150 nm.

FIG. 4E shows an SEM image of a shrunk hole array pattern with initial dimensions of 150 nm.

FIG. 4F shows an inclined view of an SEM image of the shrunk hole array pattern of FIG. 4E.

FIG. 5A shows an SEM image of a first initial imprinted pattern before undergoing a programmable miniaturization process to control the size of the shrunk pattern.

FIG. 5B shows an SEM image of the first pattern after undergoing uniaxial shrinking by 17%.

FIG. 5C show an SEM image of the first pattern after undergoing uniaxial shrinking by 32%.

FIG. 5D show an SEM image of the first pattern after undergoing uniaxial shrinking by 50%.

FIG. 5E shows an SEM image of a second initial imprinted pattern before undergoing a programmable miniaturization process to control the size of the shrunk pattern.

FIG. 5F shows an SEM image of the second pattern after undergoing uniaxial shrinking by 17%.

FIG. 5G show an SEM image of the second pattern after undergoing uniaxial shrinking by 32%.

FIG. 5H show an SEM image of the second pattern after undergoing uniaxial shrinking by 50%.

FIG. 5I shows a graph indicating the shrink ratio when controlling the heating time at temperature of 130° C.

FIG. 6A an SEM image and an optical microscope (inset) image for an initial imprinted pattern.

FIG. 6B shows an SEM image and an optical microscope (inset) image of the initial imprinted pattern after shrinking by 17%.

FIG. 6C shows an SEM image and an optical microscope (inset) image of the initial imprinted pattern after shrinking by 30%.

FIG. 6D shows an SEM image and an optical microscope (inset) image of the initial imprinted pattern after shrinking by 48%.

FIG. 6E shows a scheme of gradient pattern formation by changing the constraint conditions.

FIG. 6F shows a gradient pattern.

FIG. 7A shows an SEM image of an imprinted pattern of initial 100 nm hole size.

FIG. 7B shows an SEM image of the imprinted pattern of initial 100 nm hole size of FIG. 7A after miniaturization by 37%, hole size 55 nm.

FIG. 7C shows an SEM image of the imprinted pattern of initial 100 nm hole size of FIG. 7A after miniaturization by 46%, hole size 43 nm.

FIG. 8A shows AFM measurements of an embossed pattern that was replicated from a master pattern with initial height of 115 nm at a first temperature and a first pressure.

FIG. 8B shows AFM measurements of an embossed pattern that was replicated from a master pattern with initial height of 115 nm at a second temperature and a second pressure.

FIG. 8C shows AFM measurements of an embossed pattern that was replicated from a master pattern with initial height of 115 nm at a third temperature and a third pressure.

FIG. 8D shows a typical hot embossing cycle showing the behaviour of the process parameters force and temperature.

FIG. 8E shows a measured height of embossed patterns at different values of molding temperature and force.

FIG. 9 shows the effect of hot embossing parameters (temperature and force) on the shrink-ability of the embossed PS films.

FIG. 10A shows a schematic diagram of a first step of fabricating a polymer working stamp in a scheme of a multistep miniaturization approach using pre-stressed polymer films.

FIG. 10B shows a schematic diagram of a second step of fabricating a polymer working stamp in a scheme of a multistep miniaturization approach using pre-stressed polymer films.

FIG. 10C shows a schematic diagram of hot embossing a prestressed film in a scheme of a multistep miniaturization approach using pre-stressed polymer films.

FIG. 10D shows a schematic diagram of constrained shrinking in a scheme of a multistep miniaturization approach using pre-stressed polymer films.

FIG. 10E shows a schematic diagram of a cast PDMS mold in a scheme of a multistep miniaturization approach using pre-stressed polymer films.

FIG. 10F shows a schematic diagram of Sof-imprint polymer pattern on Si substrate.

FIG. 10G shows a schematic diagram of a RIE Si substrate in a scheme of a multistep miniaturization approach using pre-stressed polymer films.

FIG. 10H shows a schematic diagram of a clean patterned Si substrate used as a master for a next miniaturization step in a scheme of a multistep miniaturization approach using pre-stressed polymer films.

FIG. 10I is an SEM image of a Si master.

FIG. 10J is an SEM image of an imprint on prestressed film.

FIG. 10K is an SEM image of a shrunk pattern.

FIG. 10L is an SEM image of a new Si master.

FIG. 11A is a SEM image of a Si master used in a line-space pattern for a first step.

FIG. 11B is a SEM image of imprinted prestressed film having a line spaced pattern for a first step.

FIG. 11C is a SEM image of a shrunken pattern for a first step.

FIG. 11D is a SEM image of a Si master used in a line-space pattern for a second step.

FIG. 11E is a SEM image of imprinted prestressed film having a line spaced pattern for a second step.

FIG. 11F is a SEM image of a shrunken pattern for a second step.

FIG. 11G is a SEM image of a Si master used in a line-space pattern for a third step.

FIG. 11H is a SEM image of imprinted prestressed film having a line spaced pattern for a third step.

FIG. 11I is a SEM image of a shrunken pattern for a third step.

FIG. 12A is a SEM image of a Si master used in a pillar array pattern for a first step.

FIG. 12B is a SEM image of imprinted prestressed film having a pillar array pattern for a first step.

FIG. 12C is a SEM image of a shrunken pillar array pattern for a first step.

FIG. 12D is a SEM image of a Si master used in a pillar array pattern for a second step.

FIG. 12E is a SEM image of imprinted prestressed film having a pillar array pattern for a second step.

FIG. 12F is a SEM image of a shrunken pillar array pattern for a second step.

FIG. 12G is a SEM image of a Si master used in a pillar array pattern for a third step.

FIG. 12H is a SEM image of imprinted prestressed film having a pillar array pattern for a third step.

FIG. 12I is a SEM image of a shrunken pillar array pattern for a third step.

FIG. 12J is a graph of size reduction over miniaturization steps

FIG. 13A is a SEM image of a Si master for a first miniaturization step.

FIG. 13B is a SEM image of a Si master fora second miniaturization step.

FIG. 13C is a SEM image of a Si master fora third miniaturization step.

FIG. 13D is a SEM image of a shrunk pattern for a first miniaturization step.

FIG. 13E is a SEM image of a shrunk pattern for a second miniaturization step.

FIG. 13F is a SEM image of a shrunk pattern for a third miniaturization step.

FIG. 13G is a graph showing aspect ratio of the master and shrunk patterns for each miniaturization step.

FIG. 14A is a SEM image of a Si master of MCMASTER name at a first step of a miniaturization process.

FIG. 14B is a SEM image of an imprinted pre-stressed film of MCMASTER name at a first step of a miniaturization process.

FIG. 14C is a SEM image of a shrunk pattern of MCMASTER name at a first step of a miniaturization process.

FIG. 14D is a SEM image of a Si master of MCMASTER name at a second step of a miniaturization process.

FIG. 14E is a SEM image of an imprinted pre-stressed film of MCMASTER name at a second step of a miniaturization process.

FIG. 14F is a SEM image of a shrunk pattern of MCMASTER name at a second step of a miniaturization process.

FIG. 14G is a SEM image of a Si master of MCMASTER name at a third step of a miniaturization process.

FIG. 14H is a SEM image of an imprinted pre-stressed film of MCMASTER name at a third step of a miniaturization process.

FIG. 14I is a SEM image of a shrunk pattern of MCMASTER name at a third step of a miniaturization process.

Further aspects and features of the example embodiments described herein will appear from the following description taken together with the accompanying drawings.

### DETAILED DESCRIPTION

Various apparatuses, methods and compositions are described below to provide an example of at least one embodiment of the claimed subject matter. No embodiment described below limits any claimed subject matter and any claimed subject matter may cover apparatuses and methods that differ from those described below. The claimed subject matter are not limited to apparatuses, methods and compositions having all of the features of any one apparatus, method or composition described below or to features common to multiple or all of the apparatuses, methods or compositions described below. It is possible that an apparatus, method or composition described below is not an embodiment of any claimed subject matter. Any subject matter that is disclosed in an apparatus, method or composition described herein that is not claimed in this document may be the subject matter of another protective instrument, for example, a continuing patent application, and the applicant(s), inventor(s) and/or owner(s) do not intend to abandon, disclaim, or dedicate to the public any such invention by its disclosure in this document.

Furthermore, it will be appreciated that for simplicity and clarity of illustration, where considered appropriate, reference numerals may be repeated among the figures to indicate corresponding or analogous elements. In addition, numerous specific details are set forth in order to provide a thorough understanding of the example embodiments described herein. However, it will be understood by those of ordinary skill in the art that the example embodiments described herein may be practiced without these specific details. In other instances, well-known methods, procedures, and components have not been described in detail so as not to obscure the example embodiments described herein. Also, the description is not to be considered as limiting the scope of the example embodiments described herein.

It should be noted that terms of degree such as “substantially”, “about” and “approximately” as used herein mean a reasonable amount of deviation of the modified term such that the end result is not significantly changed. These terms of degree should be construed as including a deviation of the modified term, such as 1%, 2%, 5%, or 10%, for example, if this deviation does not negate the meaning of the term it modifies.

Furthermore, the recitation of any numerical ranges by endpoints herein includes all numbers and fractions subsumed within that range (e.g. 1 to 5 includes 1, 1.5, 2, 2.75, 3, 3.90, 4, and 5). It is also to be understood that all numbers and fractions thereof are presumed to be modified by the term “about” which means a variation up to a certain amount of the number to which reference is being made, such as 1%, 2%, 5%, or 10%, for example, if the end result is not significantly changed.

It should also be noted that, as used herein, the wording “and/or” is intended to represent an inclusive-or. That is, “X and/or Y” is intended to mean X, Y or X and Y, for example. As a further example, “X, Y, and/or Z” is intended to mean X or Y or Z or any combination thereof. Also, the expression of A, B and C means various combinations including A; B; C; A and B; A and C; B and C; or A, B and C.

The following description is not intended to limit or define any claimed or as yet unclaimed subject matter. Subject matter that may be claimed may reside in any combination or sub-combination of the elements or process steps disclosed in any part of this document including its claims and figures. Accordingly, it will be appreciated by a person skilled in the art that an apparatus, system or method disclosed in accordance with the teachings herein may embody any one or more of the features contained herein and that the features may be used in any particular combination or sub-combination that is physically feasible and realizable for its intended purpose.

Here, a miniaturization approach that inhibits reflow and provides for retention of shrunken patterns on pre-stressed polymer films, even at a scale of <50 nm, is described. In at least one embodiment, by applying constraints, such as but not limited to mechanical constraints, in one direction during a shrinking process, only the stress in a different (e.g., orthogonal) direction is relieved and a uniaxial shrinkage is obtained in that direction while preserving the topographical features. In at least one embodiment, the constraints may be applied in any direction, including but not limited to being applied during a first constraining step where the polymer film is constrained in a first direction, and then in one or more subsequent constraining steps where the polymer film is constrained in a subsequent direction, each subsequent direction being different than the first direction (e.g., orthogonal to, or differing by an angle that is in a range of about 0 to about 90 degrees). Then, a biaxial shrinkage is obtained by a second thermal treatment with the constraint in the different (e.g., orthogonal) direction.

The developed approach can miniaturize the features size from that of the original master pattern while preserving all of the topographical features. Thus, the height of the shrunken patterns is preserved, and well-defined patterns are generated. Nanoscale patterns with features size well below 50 nm were fabricated with high fidelity. Moreover, the effect of hot embossing parameters on the quality of the generated patterns and the effect on the ability of the embossed film to shrink to determine the appropriate hot embossing parameters was investigated. It has been demonstrated that this miniaturization approach can be programmed to fabricate different smaller size patterns from a single master mold. Varying the constraints spatially can also produce gradient shrinkages that may be of importance in certain applications. Finally, this capability has been applied to fabricate tunable and gradient plasmonic structures with different sizes and hence different optical properties that can reflect certain colors corresponding to each different size.

### Miniaturization of Hot Embossed Nano Patterns by Applying Constraints

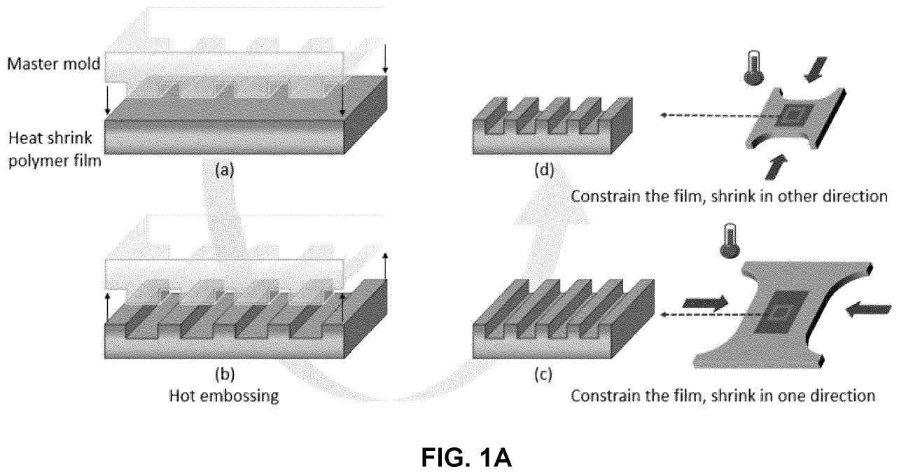

Thermal-NIL or hot embossing is a well-established fabrication process that can imprint complex structures over large areas at low-cost and high speed [22, 23]. However, fabrication of master molds which are needed for the hot embossing process is challenging and time consuming, especially for large area patterning. Heat shrinkable films can be used to reduce the features size of an original master pattern. Thus, they can generate new features at higher resolution in a scalable manner without the need of fabricating new master molds. Therefore, a combination of hot embossing with the shrinking techniques could prove valuable in developing a low-cost, rapid and scalable nanofabrication approach. Nevertheless, such efforts in the past were not successful due to the shape memory effect of the pre-stressed films that result in material reflow and loss of pattern definition. In particular, the height of the patterns were significantly reduced to a few nanometers, especially for feature sizes in the sub-micron scale. It was discovered that if the same imprinted pre-stressed film were to be thermally shrunk with uniaxial constraint, then it shrinks in the orthogonal direction with minimal loss of topographical features. With this finding, a fabrication process (see FIG. 1A) has been developed to proportionally miniaturize nanometer scale imprinted features.

As shown in FIG. 1B, in accordance with at least one embodiment, a method 100 of producing nanoscale features on a pre-stressed polymer film is provided herein. The method includes, at a step 102, imprinting the pre-stressed polymer film with a nanoscale or microscale pattern.

The method also includes, at a step 104, constraining the pre-stressed polymer film in a first direction with a first constraint

The method also includes, at a step 106, shrinking the pre-stressed polymer film in a second direction with a first heat treatment process.

The method also includes, at a step 108, releasing the first constraint.

The method also includes, at a step 110, constraining the pre-stressed polymer film in the third direction with a second constraint, the third direction being different than the first direction.

The method also includes, at a step 112, shrinking the pre-stressed polymer film in a fourth direction with a second heat treatment process.

The method also includes, at a step 114, and releasing the second constraint to produce the nanoscale features on the pre-stressed polymer film.

It should be understood that the first direction and the second direction are orthogonal, and that the third direction and the fourth direction are orthogonal. In at least one embodiment, the first direction and the third direction may be same directions and the second direction and the fourth direction may be same directions. In at least one embodiment, the first direction and the third direction are not same directions and the second direction and the fourth direction are not same directions. In at least one embodiment, the first direction and the third direction may differ by an angle that is in a range of about 0 to about 90 degrees. In at least one embodiment, the second direction and the fourth direction may differ by an angle that is in a range of about 0 to about 90 degrees. It should be understood that subsequent directions (e.g., fifth direction, sixth direction, etc.) may a same direction as any one of the first, second, third or fourth directions or may be a different direction as any one of the first, second, third or fourth directions.

Herein, the term direction is used to refer to a line or course on which the polymer film is moving (e.g., shrinking or being constrained) or is aimed to move or along which something is pointing or facing. The line or course on which the polymer film is moving may be on which the polymer film is shrinking or on which the polymer film is being constrained (i.e., tension is being applied to the polymer film).

### Determining Optimal Hot Embossing Parameters for Pattern Height and Shrink-Ability

Hot embossing is a replication process that replicates the features in the master mold into the polymer film. Thus, changing the process parameters could affect the quality of the replicated features [31,32]. As our main goal is to combine the hot embossing based pattern transfer with the heat shrink technology to fabricate smaller features while maintaining their height after shrinking, it is important to ensure the quality and identicality of the hot embossed patterns. Briefly, the hot embossing cycle consists of the following steps: heating of the polymer film and the mold to the molding temperature, while the film and the mold are brought into contact. When the molding temperature is reached, the mold and the polymer film are pressed against each other by increasing the force until it reaches the required molding force and then it is kept constant during the defined holding time. After that the cooling step starts where the temperature decreases to the demolding temperature while the force is still maintained. Finally, the force is removed and the embossed polymer film is demolded from the master mold.

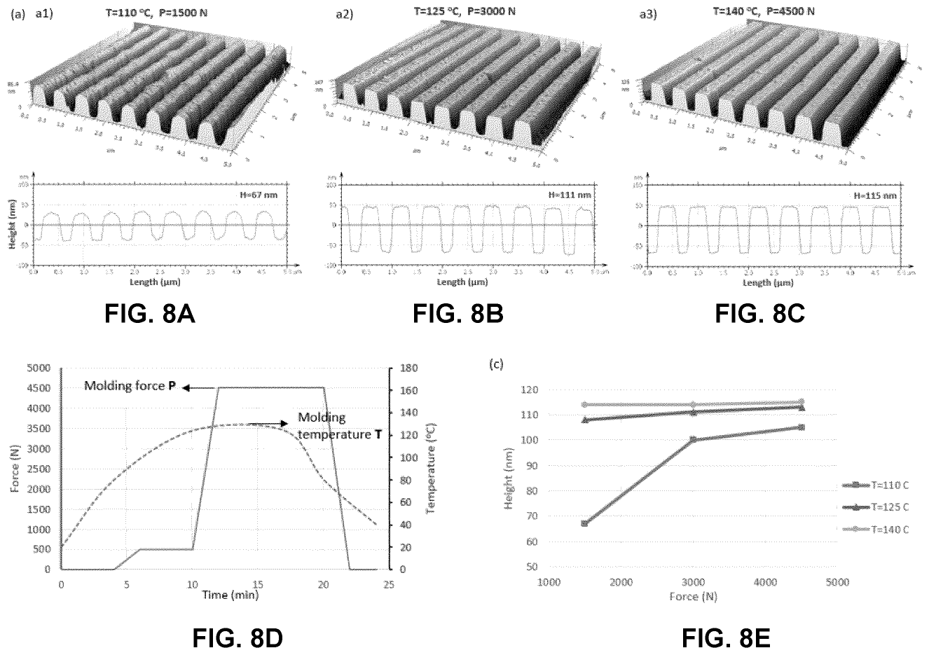

A typical representation of the time-dependent behaviour of the applied process parameters (force and temperature) is shown in FIG. 8D. First, the temperature is increased to preheat the mold and the heat shrinkable PS film to 80° C. Then, the mold and the polymer film are brought into contact while the force increases to the contact force value (500 N) and was kept constant. The temperature continues to increase until it reaches the molding temperature (T), which is above the glass transition temperature Tg of the polymer, and then kept constant. When the molding temperature is reached, the embossing force increases to reach the required molding force (P), which is held constant during the embossing time (5 min). During this step, the polymer material flows into the cavities of the mold and the features of the mold are replicated into the PS film. When the embossing time is over, the cooling step starts while the molding force is still applied. The temperature decreases to 80° C., at which the force is decreased until it is completely removed. Then, the mold and the patterned film are separated and demolded. The values of the molding force (P) and the molding temperature (T) represented in FIG. 8D are 4500 N and 125° C., respectively. These values represent the chosen parameters after the process optimization, which is discussed in the following paragraphs.

### Embossing Time (5 Min)

During this step, the polymer material flows into the cavities of the mold and the features of the mold are replicated into the PS film. When the embossing time is over, the cooling step starts while the molding force is still applied. The temperature decreases to 80° C., at which the force is decreased until it is completely removed. Then, the mold and the patterned film are separated and demolded. The values of the molding force (P) and the molding temperature (T) represented in FIG. 8D are 4500 N and 125° C., respectively. These values represent the chosen parameters after the process optimization, which is discussed in the following paragraphs.

The main process parameters for the hot embossing that affect the filling of the polymer into the mold cavities and the quality of the replicated features are the molding force (P), the molding temperature (T) and the embossing time [33,34,35]. For the nano scale patterns, it was found that the embossing time has no significant effect on the embossed patterns and a few minutes (5-6 min) are sufficient for the embossing process. Thus, the molding force and the molding temperature were studied while all other parameters were remained unchanged. Hot embossing experiments were performed on the PS heat shrinkable films at three different values of molding temperature (T) of 110° C., 125° C., and 140° C. Note that the glass transition temperature Tg of PS is around 110° C. At each T, the molding force (P) was varied at three different values of 1500 N, 3000 N, and 4500 N. AFM measurements were performed on the embossed patterns to determine the quality and the height of the patterns. FIGS. 8A, 8B and 8C shows three examples of the embossed patterns at the lowest, middle, and highest values of T and P. The initial master pattern was a line-space pattern with a line width of 300 nm and height of 115 nm. The height of the embossed patterns was measured as it can represent the filling of the mold cavities. At the lowest values of T and P (T=110° C., P=1500 N), the height of the embossed pattern was found to be 67 nm (FIG. 8A). While at the middle values of T and P (T=125° C., P=3000 N), the height was increased to be 111 nm (FIG. 8B). When the highest values of T and P were applied (T=140° C., P=4500 N), the height was increased further to 115 nm (FIG. 8C) which is the same height of the master pattern. These results show that the height of the embossed pattern increased with the increase of T and P. In addition to the height increase, the shape and the surface finish of the pattern were also improved.

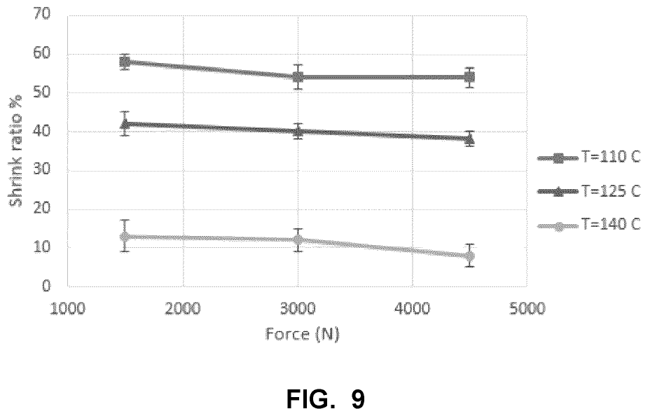

The measured heights of the patterns after hot embossing at all different values of T and P are shown in FIG. 8E. This can show the effect of increasing T and P on the height. When the pattern was embossed at a temperature equal to Tg (T=Tg=110° C.), the force had a significant effect on the height of the embossed pattern. However, when the temperature was increased over Tg the effect of the molding force was minimized as the height slightly increased. At relatively higher temperature than Tg, the embossing force had almost no effect on the height and the height of the embossed pattern reached its maximum value even at lower force values. This illustrates the effect of increasing the temperature as the polymer is soften which makes it easier for the polymer material to flow and fill the cavities in the mold. Thus, the molding temperature has an important role in achieving better replication results. It is clearly shown that the height and the shape of the replicated patterns are improved when the molding temperature and the force are increased. Therefore, applying higher temperature and force is expected to optimize the hot embossing results and hence the miniaturization process, however this is not the ideal case. Hot embossing conditions affect the ability of the heat shrinkable films to shrink. During hot embossing, the embedded stresses in the prestressed polymer film are partially released while the film is fixed in position and its size does not change. Thus, when the film is heated to allow thermal shrinking, the film does not shrink completely. In order to demonstrate the effect of hot embossing conditions on the shrink-ability of the prestressed PS films, embossed films at different values of T and P were heated to shrink. The embossed films were heated at 130° C. for 7 min. Then, the shrunk size was measured and compared to the initial size before shrinking, the results are shown in FIG. 9. It is clearly shown that the shrink ratio significantly decreased when T was increased. However, the embossing force did not significantly affect the shrink ratio. It is interesting to note that when the film was embossed at higher temperature (T=160° C.), the film completely lost its ability to shrink (shrink ratio 0%) even when it was heated for 1.5 hours at 180° C.

Therefore, to choose the appropriate hot embossing conditions for the developed miniaturization process, the conditions should attain high quality embossed patterns without significantly losing the ability to shrink. The molding temperature should be higher than Tg to achieve better replicated patterns (FIG. 8E), but not too high to affect the shrink-ability of the embossed film (FIG. 9). The molding force can be increased to improve the replicated patterns (FIG. 8E); however this increase doesn't significantly affect the shrink-ability (FIG. 9). Due to these requirements, T and P of values 125° C. and 4500 N were used as optimized hot embossing process parameters for the miniaturization process. For these values, high quality replicated patterns can be generated with high shrink-ability of shrink ratio up to 52% (when heated for longer time to shrink completely).

### Miniaturization of Hot Embossed Nano Patterns by Applying Constraints

First, a master mold was used to imprint pre-stressed polystyrene (PS) films using a hot embossing process, FIG. 1A and FIG. 1B. The film was embossed under specific conditions of force and temperature which were optimized so that the imprinting process does not affect the ability of the film to shrink.

After the hot embossing step, the film was cooled down while the embossing force was retained. At the separation temperature (50-60° C.), the patterned film was carefully separated from the master mold to avoid tearing or damage of the patterns that could happen during separation due to the difference in thermal expansion coefficients of the film and the mold, FIG. 1A.

In order to miniaturize the embossed patterns, the film was heated above its Tg to allow thermal shrinking while applying unidirectional constraints on the film, FIG. 1A. Due to this configuration, the film shrinks in a direction (shrink-direction) perpendicular to the constrained direction and a uniaxial shrinking was achieved. Then the film was cooled down to the room temperature. For a complete shrinking (biaxial shrinking), the film was constrained in the other direction and heated to allow shrinking in the shrink-direction, FIG. 1A. This process will result in proportional miniaturization of the patterns in all directions while still preserving the topographical features.

In order to demonstrate the miniaturization of hot embossed patterns using this approach, a nanoscale line-space pattern (300 nm line width and 300 nm spacing) was used. The results were compared to the conventional direct shrinking process (without constraints).

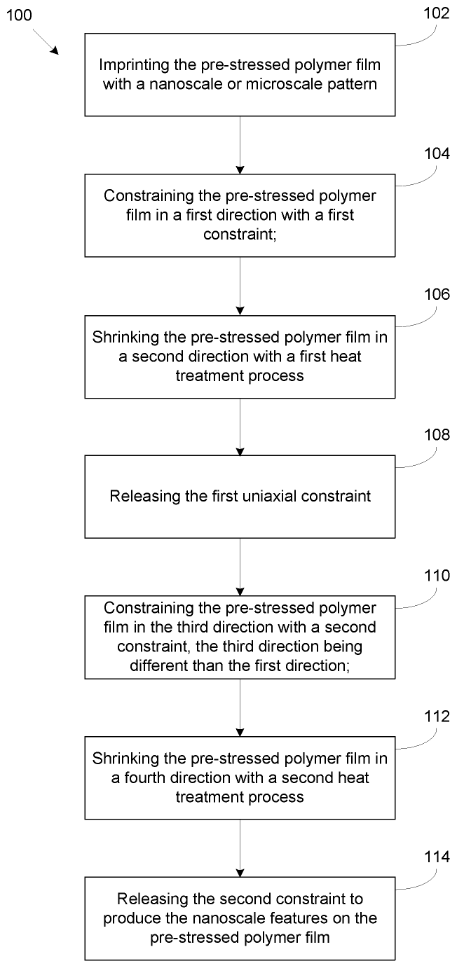

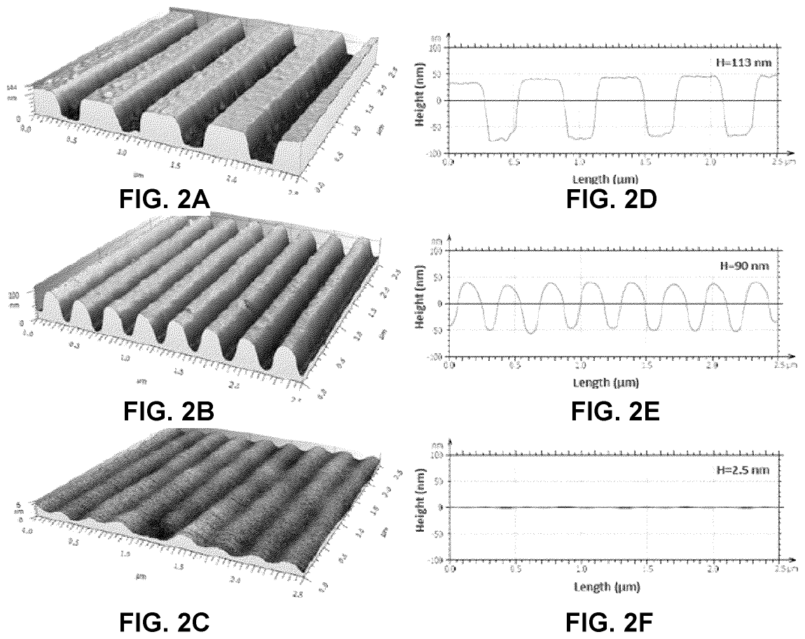

FIG. 2 shows atomic force microscopy (AFM) images and the corresponding height profile of (FIGS. 2A and 2D) the imprinted pattern by hot embossing, and the generated patterns after shrinking (FIGS. 2B and 2E) by applying constrains, (FIGS. 2C and 2F) without constraints. The height (H) of the imprinted pattern was initially 113 nm, and it slightly decreased to 90 nm after the constrained shrinking. However, it almost vanished in the case of direct shrinking where the height dramatically decreased to less than 2.5 nm.

AFM measurements of the imprinted pattern on PS film (FIG. 2A) and those formed after miniaturization by applying constraints during shrinking (FIG. 2B) and without constraints (FIG. 2C) show that the topographical features were preserved during constrained shrinking process while they were completely removed during the conventional unconstrained shrinking. The height of the imprinted pattern, which was found to be 113 nm, (FIG. 2D) reduced to 90 nm upon miniaturization with constraints applied (FIG. 2E), while it dramatically decreased to less than 3 nm (FIG. 2F) in the case of unconstrained direct shrinking. It should be noted that even though the height of the pattern slightly decreased by ˜20% (from 113 nm to 90 nm) after the constrained shrinking, the aspect ratio (ratio of the pattern height to the line width) actually increased 60% since the pattern size was reduced by ˜50% in the lateral direction. These results explicitly show that uniaxial constraints during shrinking of hot embossed patterns can not only preserve the imprinted topographical features but also increase the aspect ratio of those features. Patterns can be miniaturized by ˜50% from the original without any expensive processing.

When the pre-stressed polymer film with imprinted patterns on it is exposed to high temperatures (>Tg), the stress in the film is relieved in all directions causing a reflow of materials and therefore complete loss of the nanoscale imprinted patterns. However, by constraining the film uniaxially, an external tension is introduced which balances the internal compressive forces that manifest in that direction as the film tries to relieve its internal pre-stress. This balance not only prevents shrinkage in that direction but also maintains the topographical features embedded in the film. Since there is no constraint in the orthogonal direction, the film shrinks in that direction. The external tension in one direction is sufficient enough to prevent the complete stress relaxation in the imprinted regions of the film and therefore preserves the topographical features. In contrast, the unconstrained film is free to relax in all directions when exposed to temperatures higher than its Tg which results in the simultaneous reflow of material in all directions and loss of topographical features that were embedded. With the constrained shrinking, successful miniaturization of hot embossed patterns can be carried out with high fidelity and well-defined patterns smaller than the master pattern can be generated.

### Scalability of the Miniaturization Approach and Fabrication of Nanoscale Patterns Down to 50 nm

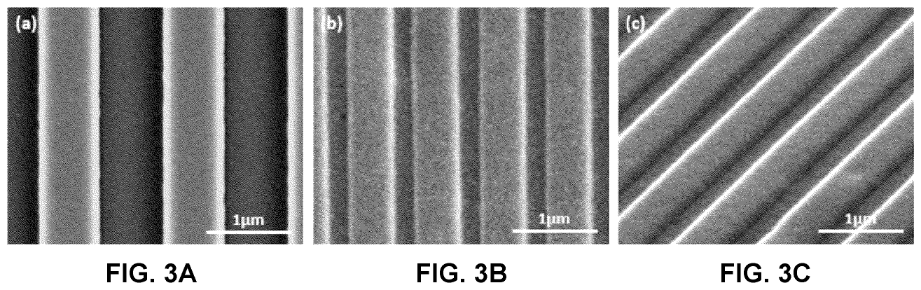

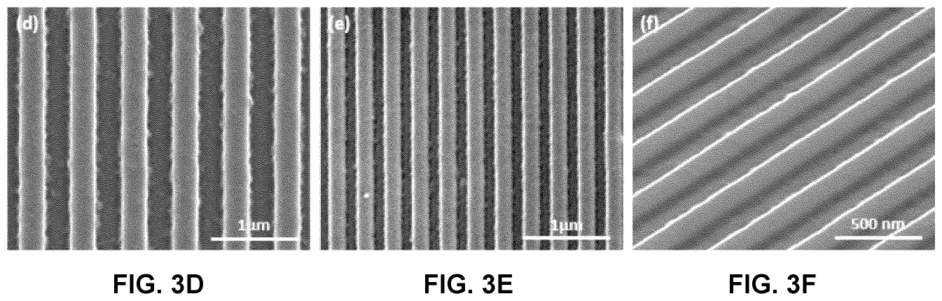

The nanofabrication method of miniaturization by constrained shrinking of the pre-stressed polymer films can enable accurate miniaturization of nanoscale patterns produced by a wide variety of methods including, lithography, nanoimprinting, hot embossing even further into the sub 100 nm scale as it overcomes the limitations of unconstrained shrinking due to stress relaxation. The scalability of this miniaturization process and its range was demonstrated by using three different dimensions of master patterns to imprint and shrink. Masters with line patterns containing line widths of 750 nm, 300 nm, and 150 nm with identical spacing were hot embossed on PS heat shrinkable films (FIGS. 3A, 3D and 3G, respectively). These patterns were miniaturized by approximately 50% after the two-step constrained shrinking process (FIGS. 3B, 3E and 3H, respectively). SEM images taken at inclined view for the shrunk patterns are shown in FIGS. 3C, 3F and 3I, respectively, demonstrate that the patterns are relatively tall and retain the topographical features in all cases. For the 750 nm pattern, after miniaturization the line width reduces to 470 nm while the spacing reduces to 280 nm (50% total reduction). For the 300 nm pattern, the line width reduces to 170 nm and the spacing to 120 nm (52% total reduction). For the 150 nm pattern, the line width reduces to 92 nm and the spacing to 56 nm (51% total reduction).

It is interesting to note that higher resolution patterns than the original patterns were achieved with high fidelity even for the smallest pattern of sub-100 nm dimensions. It should be also noted that the spacing reduced more (37-40% of the original) than the line width (56-63% of the original) due to the stresses associated with the hot embossing process at the surface layer of the polymer film. The internal compressive stresses embedded in the shrinkable film at the surface layer are partially released due to the hot embossing conditions and the polymer redistribution during patterning. When the patterned film is heated to thermally shrink, the internal compressive stresses in the core of the film push and compress the polymer material along the shrink-direction. Due to the absence of material in the spaces between the lines, the spacing is compressed and shrinks more than the line width. The partial release of the stress during hot embossing also explains why the hot embossed film shrinks by 50% overall instead of 60% with is typical for pristine pre-stressed PS films [21, 24, 25]. Despite the different shrinking ratios of the spacing and line width, highly uniform patterns with reduced dimensions were fabricated with high fidelity and reproducibility.

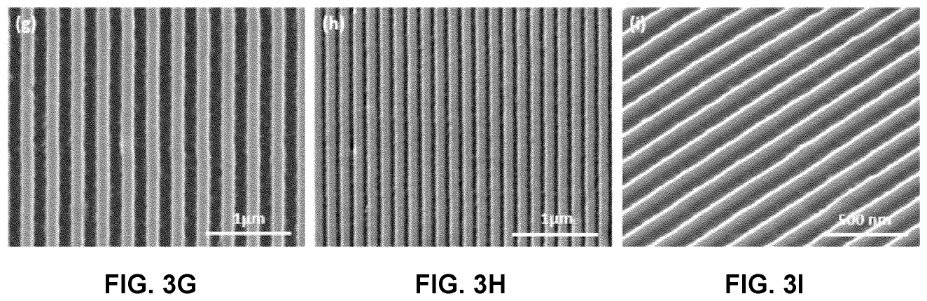

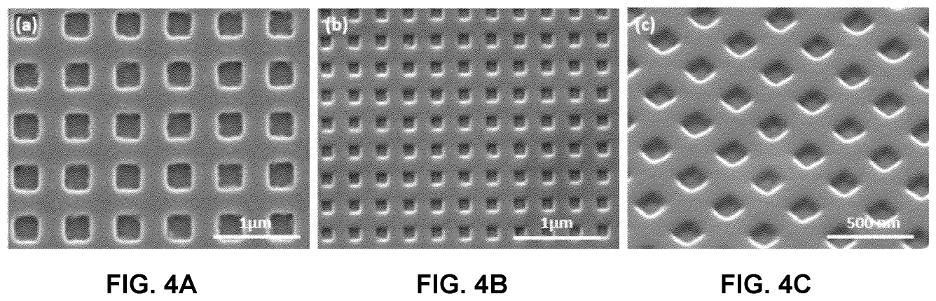

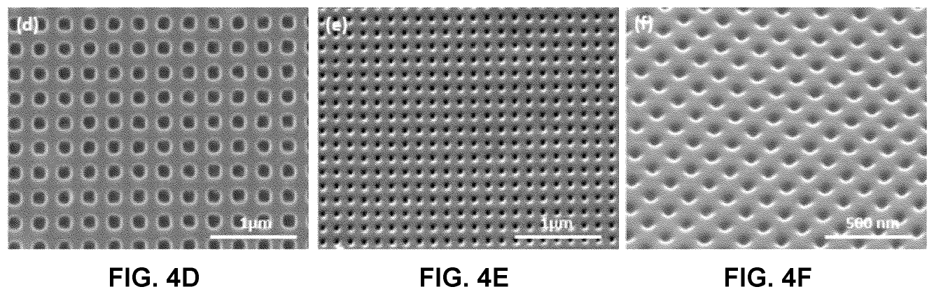

In order to show that the miniaturization process can be also used to fabricate features of different shapes other than line-space patterns, hole arrays with different dimensions were also nanofabricated by the constrained shrinking based miniaturization process. The initial master patterns were imprinted by hot embossing on PS shrinkable films. The imprinted patterns were hole arrays of square shape with hole size of 300 nm, and 150 nm (FIGS. 4A and 4D, respectively). The spacing between the holes was the same as the hole size, i.e. 300 nm, and 150 nm respectively. Following same procedures of the constrained shrinking, the patterns were miniaturized by ˜50% (FIGS. 4B and 4E, respectively). SEM images taken at inclined view for the shrunk patterns are shown in FIGS. 4C and 4F, respectively, demonstrate that the depth of these holes and topographical features are maintained. For the 300 nm hole array, after miniaturization, the hole size reduces to 135 nm while the spacing reduces to 165 nm (50% total reduction). For the 150 nm hole array, the hole size reduces to 68 nm and the spacing to 84 (49.5% total reduction).

As described in the line-space pattern, the hole size reduced (45% of the original size) more than the spacing (55% of the original) between the holes due to the stress relaxation at the surface layer of the polymer film during the hot embossing process. However, the difference between the hole size and spacing in the hole array is smaller than the difference between the line width and spacing in the line-space pattern. This can be due to the additional connections that the hole array has in the direction of the constraint as compared with the line array. Thus, in the hole array, the compressive stresses push the interconnected material in the pattern and compress it more than the separated pattern. The results show that higher resolution patterns than the initial patterns can be generated and can be applied to different shape features.

Programmable Size and Shape Patterns from a Single Master

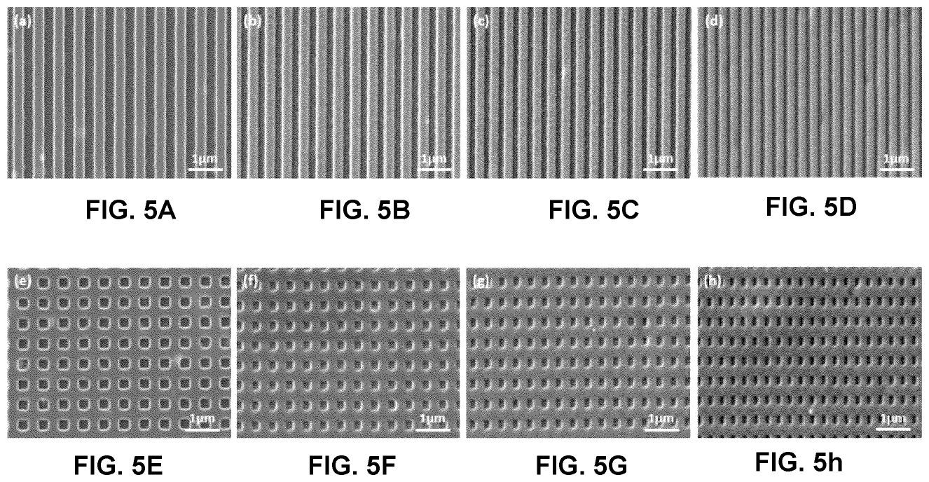

The miniaturization process using constrained shrinking of heat shrinkable films offers a programmable approach to generate smaller nanoscale structures with different pattern size and shape. Thus, scaling of nano patterns becomes possible without the need to fabricate new masters. The constraints also allow us to change the shape of the initial features by defining the shrinking direction, for example a rectangular shape can be generated from a square shape and an oval shape from a circular shape and vice versa. In order to demonstrate these capabilities, hot embossed patterns were shrunk in one direction only (uniaxial shrinking) to change the feature shape of the initial pattern. The embossed patterns were also miniaturized at different shrink ratios by controlling the heating time to create different feature sizes from same initial pattern. SEM images of the initial and shrunk patterns at different shrink ratios are shown in FIG. 5. Two initial patterns were embossed on the PS films, line-space pattern (FIG. 5A) and hole array (FIG. 5E). The feature size of the initial imprinted patterns was 300 nm with same spacing. The imprinted film was constrained and heated uniformly at 130° C. for 4.5 min. As a result, the film was shrunk in one direction by 17% shrink ratio and consequently the embossed patterns (FIGS. 5B and 5F). When the film was heated for longer time (6 min), the patterns were shrunk by 32% (FIGS. 5C and 5G). Finally, the patterned film was heated for 9 min which allowed it to shrink by nearly 50% (FIGS. 5D and 5H). The final dimensions of the shrunk line-space pattern were 175 nm for the line width and 125 nm spacing between the lines. The hole array was shrunk to 140 nm for the hole width and 160 nm spacing between the holes. Note that the final shrink ratio of ˜50% was the maximum achieve able shrink ratio of embossed PS films due to the used hot embossing parameters which affect the shrink-ability as discussed earlier.

The results show that the miniaturization process of patterned heat shrinkable films can be programmed to generate patterns of different sizes from the same master pattern. The resulted shrink ratio by carefully adjusting the shrinking time is shown in FIG. 5I. By controlling the shrinking time, the desired pattern dimensions can be produced. In addition, not only the feature size but also the feature shape can be controlled and changed by the constrained shrinking. The feature shape of the hole array was initially a square hole (FIG. 5E). After shrinking in one direction, the shape changed to a rectangular hole (FIGS. 5F, 5G and 5H). Typically, if patterns with different sizes or shapes are required, new masters must be fabricated for each pattern. However this limitation was overcome by the constrained miniaturization process of hot embossed PS shrinkable films. This programmable approach can be a cost and time effective nanofabrication method that can create higher resolution patterns than the initial patterns.

### Tunable Plasmonic Structures

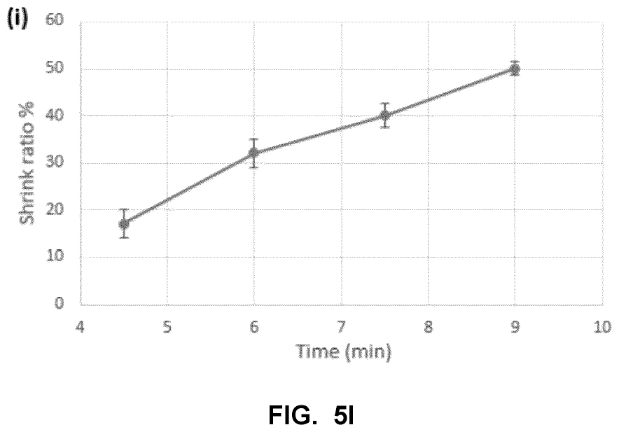

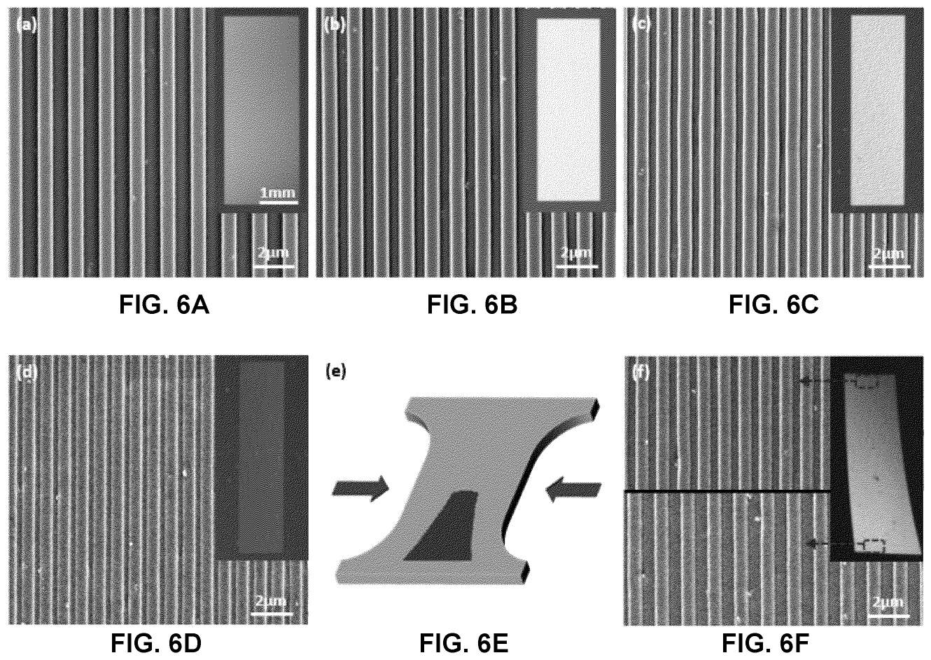

The constrained shrinking of patterned prestressed films have shown the ability to produce new patterns with programmable sizes. This approach has been applied to prototype plasmonic structures with tunable properties in a scalable manner. This can overcome a challenge in the field of plasmonics where there is a need to gradient feature size or spacing on the same substrate [39-41]. In order to demonstrate the ability to fabricate tunable plasmonic structures, a line-space pattern (grating structure) was imprinted on the PS shrinkable films by hot embossing. Then, the films were constrained and heated to perform uniaxial shrinking. Different shrink ratios were obtained by adjusting the heating (shrinking) time. The new miniaturized patterns were then coated by a thin gold layer (10 nm Au), by sputtering deposition, to activate the plasmonic effect and hence the optical properties. When a direct light is illuminated at an angle on the nanopatterned structure, the reflected light is determined by the plasmonic response of the surface [29, 30]. Depending on the shape and dimensions of the patterned surface structure, the reflected wavelengths can be controlled. If the reflected wavelength is in the visible spectrum region (400-700 nm), bright colors in the visible spectrum can be observed. SEM images taken for the initial and shrunk patterns and the corresponding optical microscope images are shown in FIGS. 6A-6F. The initial dimensions of the line-space pattern were ˜750 nm line width and ˜750 nm spacing (FIG. 6A). Such dimensions were used to allow reflection of wavelengths in the visible region. Thus, visible bright colors can be detected by the optical microscope (and also by human eye). A bright green color was reflected by the initial embossed pattern, as shown in FIG. 6A. When the pattern was miniaturized by ˜17% (4.5 min) using the programmable shrinking method, a different color (yellow) was reflected from the pattern (FIG. 6B). After ˜30% miniaturization (6 min), the reflected color changed to cyan (FIG. 6C). After further miniaturization by ˜48% (9 min), the reflected color from the pattern was blue (FIG. 6d). It can be clearly shown that the reflected colors are very uniform and homogeneous over the large, patterned area. This indicates that the generated patterns by the constrained miniaturization process have high fidelity and uniformity over relatively large area. The results show that the developed process can be applied to rapidly generate plasmonic structures with tunable dimensions and hence optical properties just by changing the duration of time over which the material was shrunk. It is also interesting to note that spatially tuned dimensions can be produced from the same pattern by modifying the constraint conditions spatially. A gradient pattern was obtained by placing the pattern closer to one of the constrained ends and relatively far from the other constrained end (FIG. 6E), instead of placing the patterned area at the middle between the constrained ends as described before (FIGS. 1C and 1D). As a result, the pattern size slightly reduced at the end that is close to the constrain (bottom of FIG. 6F) while it reduced more at the far end (top of FIG. 6F). Therefore, the shrunken dimensions of the pattern can be changed continuously along the patterned area. This continuous change resulted in a multicolor gradient pattern with colors ranging from green to blue, as seen in the inset of FIG. 6F. More broadly, these results indicate that by modulating the tension in the constraints spatially one can create any complex pattern of shrinkages which could be suitable in a variety of programmed miniaturization of nanoscale features.

### Tunable Fabrication of Feature Sizes Below 50 nm

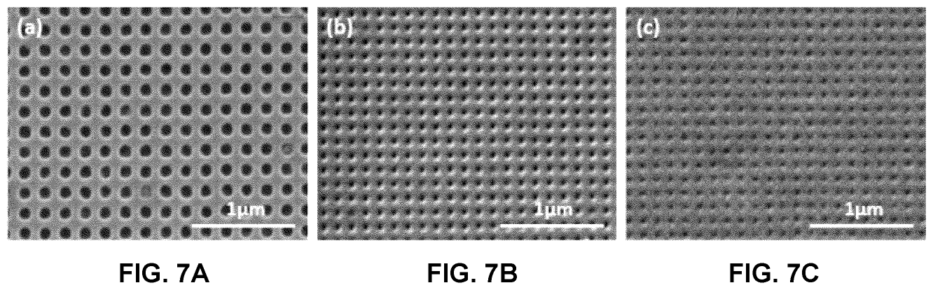

Feature sizes below 50 nm are of importance in IC processing where pattern definition at this scale are required to produce extremely small transistors. Features in this dimension are produced with high cost and complexity by using either ArF immersion lithography or EUV lithography. One way to lower the cost and complexity is to produce patterns at larger dimension (50-100 nm) and shrink them to lower dimensions. In order to determine the extension of our process to dimensions lower than 50 nm, a study using 100 nm hole array (FIG. 7A) was conducted which was subjected to constrained miniaturization with different heating time to achieve different final dimensions. The imprinted pattern was successfully miniaturized by 37% (7 min), where the hole size reduced to 55 nm and spacing between them reduced to 72 nm (FIG. 7B). After further miniaturization (8.5 min), a total reduction of 46% was achieved. The hole size reduced to 43 nm while spacing reduced to 65 nm (FIG. 7C). These results show that the constrained miniaturization process can achieve feature sizes below 50 nm easily. One of the challenges in visualizing the features produced at this scale especially in a polymer is the need to metalize it. Deposition of even a thin gold layer (10-15 nm) in thickness results in loss of resolution of the embedded features as can be seen in (FIG. 7C). Nevertheless, these results show a promising fabrication and miniaturization process that can accurately produce high resolution features at sub-50 nm dimensions. The theoretical limit of this approach may be the diameter of the uncoiled polymer used in the film which can be anywhere between 1-10 nm depending on the molecular weight of the polymer used. Conclusion

In summary, a miniaturization approach of the hot embossed patterns using heat shrinkable films by applying directional constrains to control the polymer flow during shrinking process has been developed. This approach overcomes the limitation that the hot embossed features almost disappear after direct shrinking. Using the constrained miniaturization, the height of the shrunk patterns increased from 2.2% to 80%. Moreover, new smaller patterns with higher resolution were fabricated from a single master. Nanoscale patterns with features size as small as 56 nm were fabricated with high fidelity over large area. This nanofabrication ability offers rapid fabrication of new masters that has significant advantages over master fabrication by direct-write methods in terms of cost and scalability. The influence of hot embossing process parameters on the quality of the replicated patterns and the shrink-ability of the heat shrinkable films was demonstrated in order to optimize the miniaturization process. It has been shown that the developed process can be programmed to change the features size and shape. These capabilities were applied to fabricate tunable plasmonic structures by continuously changing the pattern dimensions and hence controlling optical properties. This process shows a simple, rapid, cost effective and scalable nanofabrication approach that can be used for a wide range of applications including plasmonic structures with tunable wavelengths, high capacity storage devices or fabrication of higher resolution masters for soft lithography and nanoimprint lithography.

### Experimental Section

Hot embossing: Polystyrene heat shrinkable films (Graphix Shrink Film, Maple Heights, Ohio) were used as a polymer substrate where the nano patterns were embossed onto it. Hot embossing equipment (EVG520 HE) was used. Master stamps were obtained from EVG and used to imprint the PS films. The PS film was cut into 4 inch size and placed on a 4 inch glass wafer that was used as a carrier. The master stamp was then placed on top of PS film inside the hot embossing chamber. After closing the chamber, both top and bottom plates were warmed up at 80° C., and the chamber was evacuated to the working vacuum pressure. The piston was then moved down to bring the master stamp and substrate into contact at a contact force of 500 N (which is the minimum allowable force). The temperature of both plates was continuously increased to the desired embossing temperature, at which the force also increased to the embossing force value. The embossing time was 5 min where the force and temperature were held constant. After that, the temperature started to decrease until reached 80° C., at which the piston moved up and the force was removed (the demolding temperature was around 60° C. when the force was completely removed). The chamber was then vented and the sample was removed from the chamber. Immediately, the master stamp was separated from the imprinted film by inserting a thin razor blade between them at the edge and carefully separating them. During hot embossing optimization (see supplementary information), only the embossing temperature and force were changed while all other parameters were kept constant. The optimized values of temperature and force were 125° C. and 4500 N, respectively. These values were used for all experiments represented in this work.

Constrained miniaturization: After the nano patterns were imprinted onto the PS film, the film was cut into a square with the patterned area in the middle. Then, the film was placed on a silicon wafer and clamped by paper binder clips at two opposite ends while the patterned area was at the middle. The sample was heated at an oven at 130° C. for the desired shrinking time. Then, the sample was removed outside the oven and left for a few minutes to cool down at room temperature. As a result, the film was miniaturized in one direction only (shrink direction) and a uniaxial shrinking was obtained. For a biaxial shrinking, the film was then clamped at the other two ends while keeping the patterned area at the middle. Then, it was placed in the oven at same temperature and removed from the oven after shrinking. The shrinking time was varied to obtain different shrink ratios.

Imaging and characterization: SEM images of the fabricated patterns onto PS films before and after shrinking were taken using JEOL JSM-7000F scanning electron microscope. All PS samples were coated with a thin gold layer (5-8 nm) for preparation prior to SEM imaging. The 3D topography and height profile of nano patterns were obtained by atomic force microscope TOSCA 400 using tapping mode. Optical microscope images of the plasmonic structures were taken using OLYMPUS SZ61 and attached camera Infinity1. The optical microscope was used to demonstrate the reflected different colors based on tuning the dimensions of the shrunk patterns. White LED light was pointed on the samples at a fixed incident angle, and the samples were placed at a fixed position with respect to the light source and the objective lens of the microscope. This configuration was used for comparing the different reflected colors based only on the variation of the pattern dimensions.

### Multi-Step Miniaturization Process

Nanoimprint lithography is a well-established fabrication process which is used to replicate master patterns onto another substrate over large area at high throughput and low cost. However, fabrication of master molds required for the nanoimprint lithography process is challenging. Master molds are primarily fabricated by electron beam lithography or focused ion beam techniques which require expensive equipment (several million $) and long processing time (tens of hours) particularly for large area patterning. Thus, developing a fabrication process that can create nanoimprint lithography masters without using such complex processes could be valuable for rapid, low cost and scalable nanofabrication. One approach that can be pursued is to create low resolution patterns using scalable and high throughput fabrication methods such as photolithography and then proportionally miniaturize that microscale pattern into a nanoscale pattern.

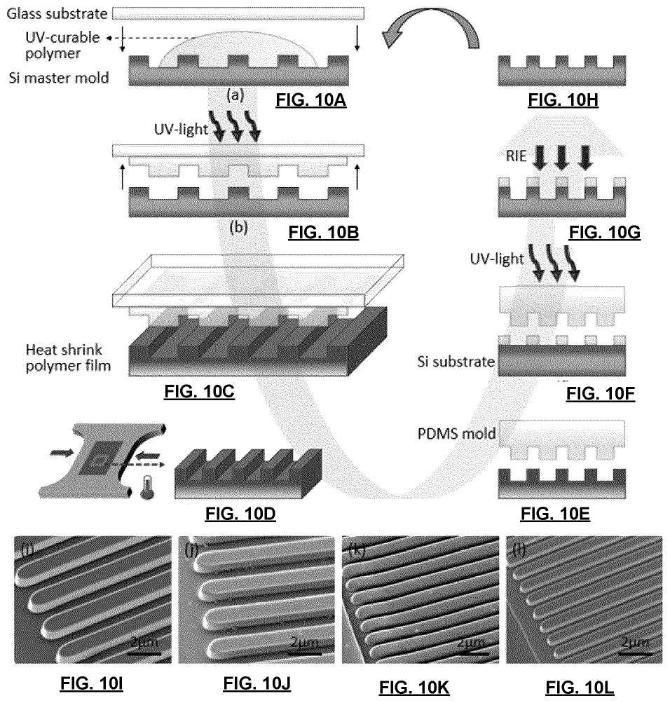

Following this approach, a multi-step miniaturization approach has been developed based on constrained shrinking of hot embossed pre-stressed polymer films to significantly reduce the size of the initial microscale patterns into the nanoscale while maintaining the topographical features. The developed approach allows the use of the shrunk pattern from a previous step as the master for the next miniaturization cycle which can be repeated iteratively in order to achieve the required resolution. A schematic illustration of the multi-step miniaturization process is shown in FIG. 10.

First, a Si master mold was fabricated using direct laser writing to create microscale (1 μm) patterns although they can be also fabricated by photolithography. Then, a polymer working stamp was replicated from the Si master mold to be used directly to imprint the pre-stressed polymer films. Although the Si master can be used directly for hot embossing, the polymer working stamp was found to be better for demolding of the imprinted film from the stamp (see supplementary information, section 1) [36][37]. The working stamp was fabricated using UV-curable polymer that was attached to a glass substrate and cured under UV light source, FIGS. 10A and 10B. Then, a polystyrene (PS) heat shrinkable film was imprinted using the fabricated working stamp in a hot embossing process under optimized conditions of molding force, temperature and time, FIG. 10C. These conditions were optimized to ensure the quality of the imprinted patterns while not affecting the ability of the embossed film to shrink. After hot embossing, the film was carefully demolded from the stamp at a specific separation temperature to avoid damage or deformation of the imprinted patterns during separation.

In order to shrink the patterned film, the film was mechanically constrained in one direction and heated above its glass transition temperature which allowed shrinking only in the orthogonal direction, FIG. 10D. Then, to obtain biaxial shrinkage, the film was constrained in the orthogonal direction and heated. As a result, the size of the patterned features reduced without losing the topographical features. Now, the shrunk patterns were used to generate a new master to be used for the next miniaturization cycle. After thermal shrinking, the surface of the shrunk film was not completely flat compared to a Si substrate. Besides, the edges and sidewalls of the shrunk features become more curved due to softening of the polymer during heating. Finally, the aspect ratio of the structures increased which can result in instability of the line features especially at the nanoscale. Thus, it was found that fabricating an intermediate Si master was better than using the shrunk PS film directly in terms of obtaining a completely flat substrate surface and decoupling the aspect ratio of the structure from the shrink dynamics enabling precise structures with vertical sidewalls even in the nanoscale (see supplementary information, section 4).

In order to generate the new master, polydimethylsiloxane (PDMS) was cast on the shrunk PS film (FIG. 10E) and used to transfer the patterns onto a Si substrate by soft UV imprint lithography (FIG. 10F). Then, the transferred resist pattern was then used as a mask to etch the Si substrate by RIE, FIG. 10G. The RIE was optimized using mixed gas process to successfully transfer patterns into the Si substrate (see supplementary information, section 2). Finally, the etched Si substrate was cleaned to remove the remaining resist mask and was used as a master for a next miniaturization cycle, FIG. 10H. Scanning electron microscope (SEM) images of the initial master, imprinted PS film, shrunk film, and the new Si master are shown in FIGS. 10I, 10J, 10K and 10L, respectively as an example of the feature evolution through the complete miniaturization cycle. As shown in FIGS. 10A-L, the pattern was significantly miniaturized after shrinking while the topographical features were preserved. In contrast, direct shrinking resulted in losing topographical features where the pattern height was dramatically decreased (see supplementary information, section 3). It can be noted that the edges of the shrunk pattern became curved (FIG. 10K) compared to the imprinted pattern before shrink and the height is maintained (FIG. 10J). However, a pattern with well-defined edges was obtained after RIE of a Si substrate (FIG. 10L) which allows faithful reproduction of the pattern in the next miniaturization step. Due to the introduction of the intermediate Si transfer stamp using the soft UV imprint lithography followed by RIE, the master produced after each step can have independent control over miniaturization in the X-Y and Z directions and enable successful and proportionate miniaturization over a large number of steps. The multi-step miniaturization approach allows reducing the size of the initial patterns several times to nanoscale dimensions and generate new masters of smaller size patterns.

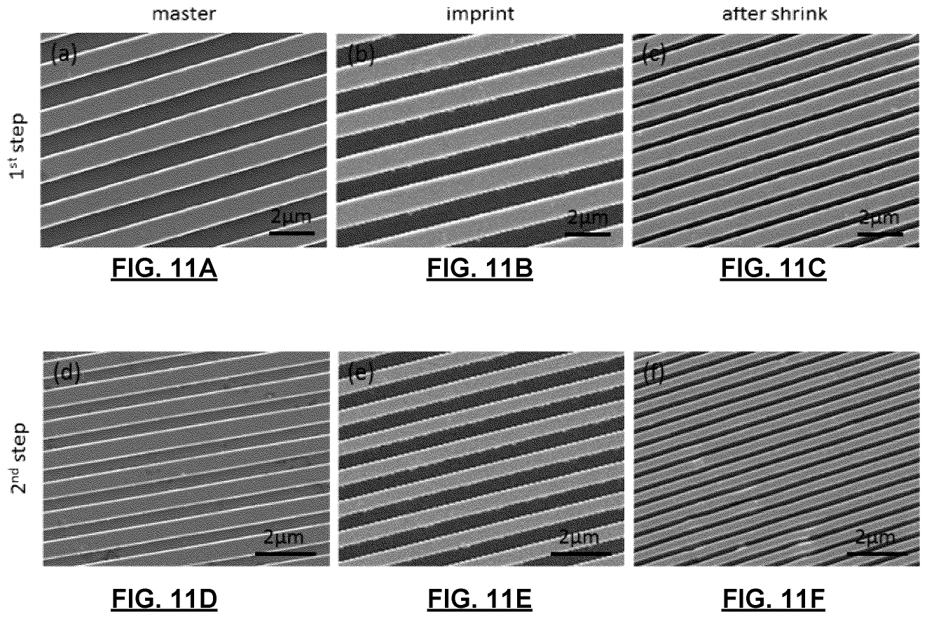

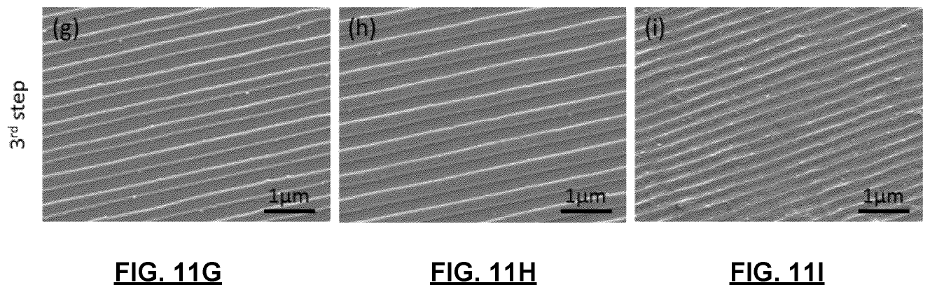

The multi-step miniaturization approach can be used as a nanofabrication method that can reduce the size of larger patterns several times down to nanoscale. This approach demonstrates that constrained shrinking of hot embossed patterns on pre-stressed films can generate well defined patterns at higher resolution which then can be used as a master for further miniaturization steps even at 100 nm scale. The scalability of this approach was demonstrated by miniaturization of a micrometer master pattern into approximately 100 nm pattern over three miniaturization steps. The initial master pattern is a line-space pattern with a line width of 1 m and 1 m spacing (FIG. 11A), which was fabricated by using a laser lithographic process. After hot embossing, the imprinted pattern on the PS shrinkable film has same dimensions of the master (FIG. 11B). The patterned film was then miniaturized by applying constrained shrinking which resulted in 50% reduction in size approximately (FIG. 11C). The shrunk pattern was used to fabricate a new Si master which was used for the next miniaturization cycle.

Following the procedures described in FIGS. 10A-10L, the miniaturization process was repeated for three cycles. The initial master and the new fabricated masters that were used for the three miniaturization cycles are shown in FIGS. 11A, 11D and 11G. The imprinted patterns on pre-stressed films are shown in FIGS. 11B, 11E and 11H. The shrunk patterns after each miniaturization step are shown in FIGS. 11C, 11F and 11I. After the first miniaturization step, the pattern size was shrunk by 50%, the line width reduced to 675 nm and the spacing to 320 nm. After the second step, the line width reduced to 280 nm and the spacing to 190 nm, showing 77% total reduction from the initial pattern. After the third miniaturization step, the line width reduced to 130 nm while the spacing reduced to 100 nm, which resulted in 89% total reduction compared to the initial pattern. The results of the multi-step miniaturization approach show that from a single master pattern, three higher resolution patterns were fabricated with high fidelity achieving features size as small as 100 nm for the smallest pattern. It should be noted that the spacing between the lines reduced more than the line width itself probably because of the effect of the imprinting process. When the imprinted film is thermally heated, the compressive stresses embedded in the pre-stressed film are released leading to shrink the polymer material into smaller size. However, the imprinting process that creates the features also plastically deforms the material and introduces additional stresses at the surface in addition to the pre-stress in the bulk. During the imprint process material is moved from the spacing region and into the line width region. This creates a large stress at the surface in the spacing as compared with that in the linewidth region. Therefore, release of this stress by thermal shrinking can potentially shrink the spacing more than the linewidth. Since the stress induced is dependent on the imprinting process and the amount of material displaced, one would expect that the asymmetry in the shrinkage will reduce as smaller and smaller patterns are imprinted. This is seen in the results obtained where the asymmetry in the shrinkage is larger when the 1 l·tm patterns are imprinted as compared with smaller patterns. Here, the applied hot embossing conditions lead to 5055% shrink ratio, instead of 60% shrink ratio for typical PS shrinkable films [37, 38]. Each miniaturization cycle takes ˜3 hrs to complete. Therefore, a size reduction from 1 l·tm to ˜100 nm can be accomplished over 3 cycles which will take about 9 hrs. This compares favorably with direct write nanolithography methods such as e-beam which take ˜24 hours for 1 cm². It should be noted

### Aspect Ratio of the Fabricated Nanopillar Array

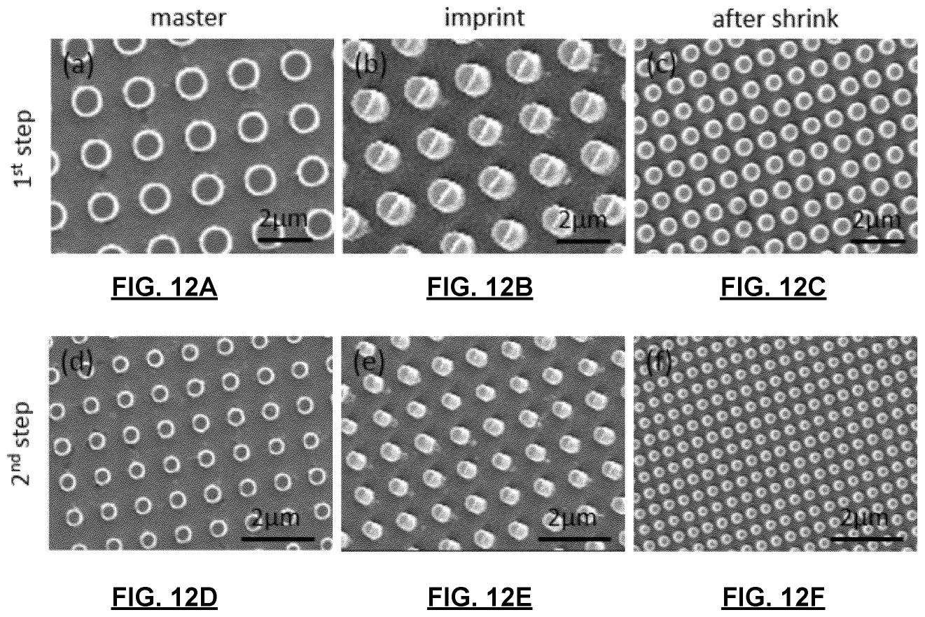

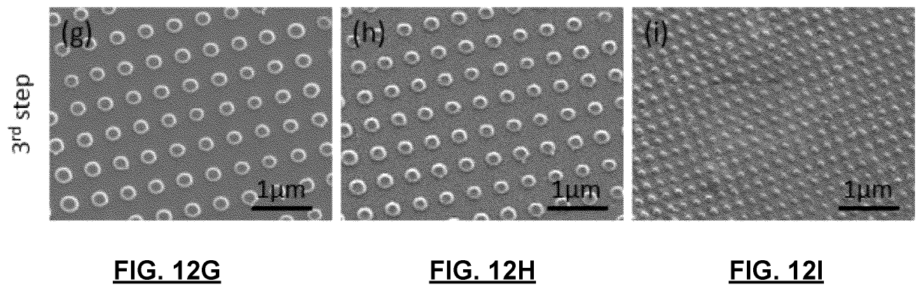

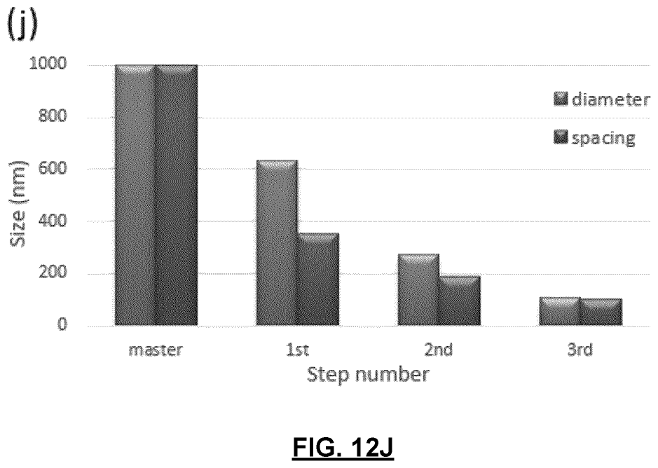

The multi-step miniaturization process can be used for nanofabrication of different feature shapes. In order to demonstrate the variety of features that can be miniaturized, pillars array was fabricated. The initial master of the pillars array has circular pillars of 1 m diameter with similar spacing between pillars (FIG. 12A). The initial pattern was imprinted and miniaturized for three sequential miniaturization cycles. The initial master and the following fabricated masters are shown in FIGS. 12A, 12D and 12G. The imprinted patterns on PS films after hot embossing are shown in FIGS. 12B, 12E and 12H. The miniaturized patterns after constrained shrinking are shown in figure FIGS. 12C, 12F and 12I After the first miniaturization step, the pillars diameter reduced from 1 m to 630 nm while the spacing reduced to 350 nm showing an overall reduction of 51%. After the second step, the pillars diameter reduced further to 275 nm and spacing to 190 nm achieving 77% total reduction in size from the initial master. After the third miniaturization step, the pillars diameter reduced more to 105 nm and the spacing to 100 nm, which resulted in a significant total reduction of 90% compared to the initial pattern. The proportional size reduction of the pillar array over three miniaturization steps is shown in FIG. 12J. Similar to the line-space pattern, the spacing between pillars shrinks more than the pillars diameter due to the stress induced during the imprinting process. However, the difference between pillars diameter and spacing decreases when the shrunk pattern was

transferred into a Si substrate to fabricate a master for the next step. After patterning the UV-curable polymer mask on the Si substrate (FIG. 10F), the residual polymer layer was removed by a quick RIE using Oxygen to expose the Si surface. During this RIE process, the polymer pattern features were also slightly etched in the lateral directions which leads to reduction the pillar's diameter and increase in spacing between them. Then, the pattern was transferred to the Si substrate by selective RIE of Si. The results show that the pattern integrity was maintained and high resolution patterns were fabricated with 10× reduction in size of the original pattern.

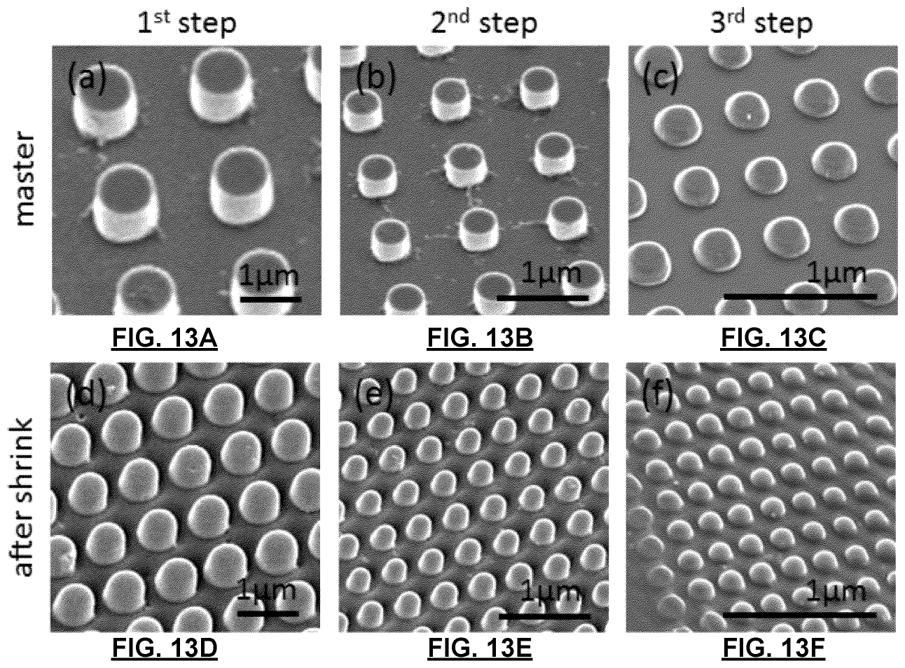

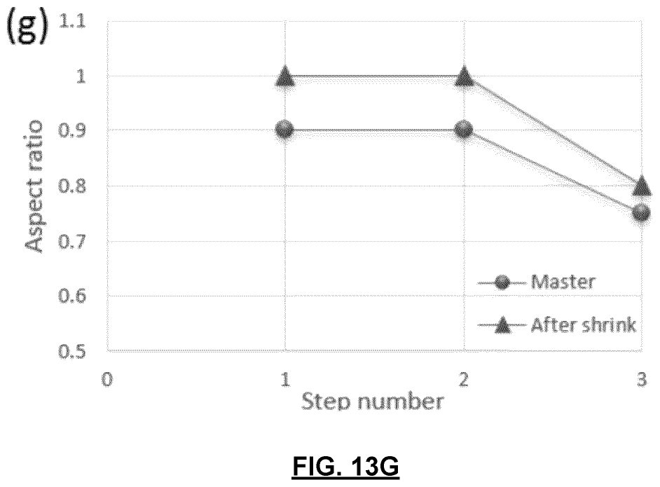

The multi-step miniaturization approach is based on shrinking patterns on pre-stressed polymer films that were imprinted by hot embossing. However, direct shrinking of hot embossed patterns results in decrease in the height of the patterns dramatically and the patterns tend to disappear after shrinking (see supplementary information, section 3). As a result, the aspect ratio is also dramatically reduced. In contrast, the developed constrained shrinking process allows to reduce the patterns size without losing the topographical features. In particular, the height of the patterns is retained or slightly decreased when applying directional constraints during shrinking while the in plane feature size dramatically reduces. Thus, the aspect ratio is expected to increase which is considered an advantage in nanofabrication. However, increase in aspect ratio during successive steps can result in tall and weak structures that can prevent precise pattern imprinting. The intermediate step to transfer the patterns obtained from constrained shrinkage onto a Si master allows for independent control of the height of the pattern and therefore the aspect ratio over several miniaturization cycles. FIGS. 13A-13G shows the aspect ratio of the pillars array over three miniaturization cycles. For each cycle, SEM images were taken at an inclined view for the master patterns (FIGS. 13A, 13B and 13C) and the shrunk patterns (FIGS. 13D, 13E and 13F) in order to demonstrate the height of fabricated pillars. The aspect ratios of the master and shrunk patterns are shown in FIG. 13G. It can be seen that the aspect ratio of features on the shrunken films increased after constrained shrinking compared to the initial master for each miniaturization step. In addition, the aspect ratio was maintained for the first and second miniaturization cycles as the height of the patterns in the master was controlled by RIE of the Si intermediate master. However, the aspect ratio of the master and shrunk patterns of third step was lower. It may be due to an unoptimized RIE process when fabricating the third step master at such small dimensions. The polymer mask was etched quickly, and hence deeper etch of the Si could not be achieved. However, in the future a more resistant mask can be used and RIE process can be optimized to maintain the required aspect ratio [40][41]. Of note is that DRIE is a widely used process in integrated circuit nanofabrication and high resolutions <50 nm are obtainable with good process control.

### Fabrication of Complex Patterns

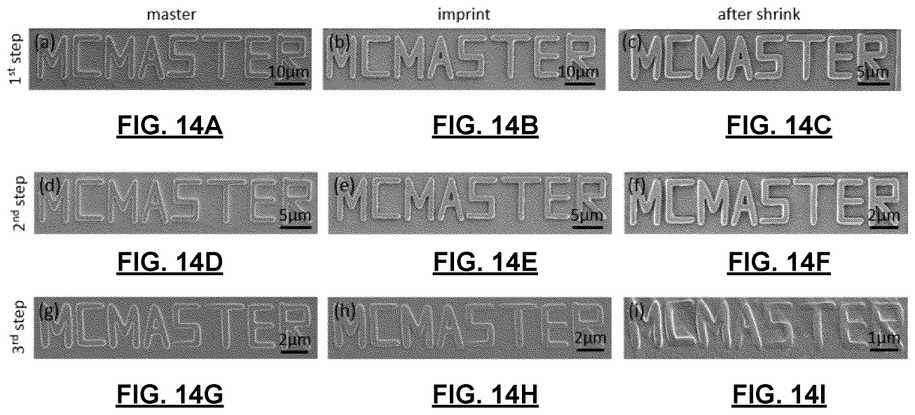

In order to demonstrate that the multi-step miniaturization approach is versatile, a more complicated pattern with alphabets, (“MCMASTER”) was also fabricated and miniaturized for three sequential miniaturization cycles (FIGS. 14A-14I). The total reduction in size that was achieved after each miniaturization cycle was 51%, 78%, and 88% respectively. The line that forms each letter of MCMASTER has an initial width of 2 m. After each miniaturization step the line width was reduced to 970 nm, 450 nm, and 240 nm respectively. It can be seen that all different letters were miniaturized in the same proportion even for the letters that include inclined lines such as “A”. This indicates that the technique is versatile and can proportionally miniaturize not only line and dot patterns but any complex pattern of choice. It can be noticed that the shrunk pattern of the third miniaturization step was slightly distorted (FIG. 14I). This may be due to misalignment in the constrained direction during shrinking process. Often when the constraints on either side are not aligned with each other such distortions can occur. Use of a more optimized jig for constraining would address this issue. Nevertheless, the results show that the multi-step miniaturization approach can be used for almost any kind of patterns and different feature shapes to significantly reduce the size of the original features from a micrometer scale into nanoscale. This can overcome the challenges of directly fabricating nano patterns using conventional photolithography methods.

The combination of constrained shrinking with multistep miniaturization allows patterns that are easily producible on a micrometer scale with optical lithography or other such methods to be reduced by at least an order of magnitude in dimension to the nanometer scale. The process is highly repeatable and consistent and only dependent on the material property (amount of pre-stress embedded) of the film used. Furthermore, the process tools that are used such as deep reactive ion etching systems are widely available and lower in cost as compared to e-beam lithography systems. Due to its many features it has the potential to democratize the production of nanoscale patterns in facilities that may not have access to expensive tools such as a e-beam of focused ion beam writers.

### REFERENCES

[1] E. M. Sebastian, S. K. Jain, R. Purohit, S. Dhakad, and R. Rana, “Nanolithography and its current advancements,” Materials Today: Proceedings, vol. 26, pp. 2351-2356, 2020.
[2] S. Y. Chou and P. R. Krauss, “Imprint lithography with sub-10 nm feature size and high throughput,” Microelectronic Engineering, vol. 35, pp. 237-240, 1997.
[3] A. Cattoni, E. Cambril, D. Decanini, G. Faini, and A. Haghiri-Gosnet, “Soft UV-NIL at 20 nm scale using flexible bi-layer stamp casted on HSQ master mold,” Microelectronic Engineering, vol. 87, pp. 1015-1018, 2010.
[4] H. Schift, “Nanoimprint lithography: An old story in modern times? A review,” Journal of Vacuum Science & Technology B: Microelectronics and Nanometer Structures Processing, Measurement, and Phenomena, vol. 26, pp. 458-480, 2008.
[5] M. C. Traub, W. Longsine, and V. N. Truskett, “Advances in nanoimprint lithography,” Annual review of chemical and biomolecular engineering, vol. 7, pp. 583-604, 2016.
[6] J. Chen, J. Shi, A. Cattoni, D. Decanini, Z. Liu, Y. Chen, and A.-M. Haghiri-Gosnet, “A versatile pattern inversion process based on thermal and soft UV nanoimprint lithography techniques,” Microelectronic Engineering, vol. 87, pp. 899-903, 2010.
[7] R. Menon, A. Patel, D. Gil, and H. I. Smith, “Maskless lithography,” Materials Today, vol. 8, pp. 26-33, 2005.
[8] A. Pimpin and W. Srituravanich, “Review on micro- and nanolithography techniques and their applications,” Engineering Journal, vol. 16, pp. 37-56, 2012.
[9] B. Kwon and J. H. Kim, “Importance of molds for nanoimprint lithography: hard, soft, and hybrid molds,” Journal of Nanoscience, vol. 2016, 2016.
[10] Jeong, J. Park, K. Lee, J. Jang, C. Lee, H. Kang, C. Yang, and S. Suh, “Fabrication of low-cost mold and nanoimprint lithography using polystyrene nanosphere,” Microelectronic Engineering, vol. 87, pp. 51-55, 2010.
[11] F. D. Arisoy, I. Czolkos, A. Johansson, T. Nielsen, and J. J. Watkins, “Low-cost, durable master molds for thermal-NIL, UV-NIL, and injection molding,” Nanotechnology, vol. 31, p. 015302, 2019.
[12] A. Lendlein, Shape-memory polymers vol. 226: Springer, 2010.
[13] J. Hu, Y. Zhu, H. Huang, and J. Lu, “Recent advances in shape-memory polymers: Structure, mechanism, functionality, modeling and applications,” Progress in Polymer Science, vol. 37, pp. 1720-1763, 2012.
[14] S. Lin, E. K. Lee, N. Nguyen, and M. Khine, “Thermally-induced miniaturization for micro- and nanofabrication: progress and updates,” Lab on a Chip, vol. 14, pp. 3475-3488, 2014.
[15] P. T. Mather, X. Luo, and I. A. Rousseau, “Shape memory polymer research,” Annual Review of Materials Research, vol. 39, pp. 445-471, 2009.
[16] W. Small IV, P. Singhal, T. S. Wilson, and D. J. Maitland, “Biomedical applications of thermally activated shape memory polymers,” Journal of materials chemistry, vol. 20, pp. 3356-3366, 2010.
[17] A. Yokoo, K. Wada, and L. C. Kimerling, “Pattern size reduction of nanoprint-fabricated structures on heat-shrinkable film,” Japanese Journal of Applied Physics, vol. 46, p. 6395, 2007.
[18] X. Zhu and T. Cui, “Polymer shrinkage of hot embossed microstructures for higher aspect ratio and smaller size,” Sensors and Actuators A: Physical, vol. 195, pp. 21-26, 2013.
[19] X. M. Zhao, Y. Xia, D. Qin, and G. M. Whitesides, “Fabrication of polymeric microstructures with high aspect ratios using shrinkable polystyrene films,” Advanced materials, vol. 9, pp. 251-254, 1997.
[20] X.-M. Zhao, Y. Xia, O. J. Schueller, D. Qin, and G. M. Whitesides, “Fabrication of microstructures using shrinkable polystyrene films,” Sensors and Actuators A: Physical, vol. 65, pp. 209-217, 1998.
[21] S. Sayed and P. R. Selvaganapathy, “Multi-step proportional miniaturization to sub-micron dimensions using pre-stressed polymer films,” Nanoscale Advances, vol. 2, pp. 5461-5467, 2020.
[22] S.-M. Park, X. Liang, B. D. Harteneck, T. E. Pick, N. Hiroshiba, Y. Wu, B. A. Helms, and D. L. Olynick, “Sub-10 nm nanofabrication via nanoimprint directed self-assembly of block copolymers,” ACS nano, vol. 5, pp. 8523-8531, 2011.
[23] J. Sun, J. Zhuang, Y. Liu, H. Xu, J. Home, E. K. Wujcik, H. Liu, J. E. Ryu, D. Wu, and Z. Guo, “Development and application of hot embossing in polymer processing: a review,” ES Materials & Manufacturing, vol. 6, pp. 3-17, 2019.
[24] D. Nguyen, D. Taylor, K. Qian, N. Norouzi, J. Rasmussen, S. Botzet, M. Lehmann, K. Halverson, and M. Khine, “Better shrinkage than shrinky-dinks,” Lab on a Chip, vol. 10, pp. 1623-1626, 2010.
[25] C. M. Gabardo, Y. Zhu, L. Soleymani, and J. M. Moran-Mirabal, “Bench-top fabrication of hierarchically structured high-surface-area electrodes,” Advanced Functional Materials, vol. 23, pp. 3030-3039, 2013.
[26] D. Graham-Rowe, “Tunable structural colour,” Nature Photonics, vol. 3, pp. 551-553, 2009.
[27] Y. Shen, V. Rinnerbauer, I. Wang, V. Stelmakh, J. D. Joannopoulos, and M. Soljacic, “Structural colors from Fano resonances,” Acs Photonics, vol. 2, pp. 27-32, 2015.
[28] A. Kristensen, J. K. Yang, S. I. Bozhevolnyi, S. Link, P. Nordlander, N. J. Halas, and N. A. Mortensen, “Plasmonic colour generation,” Nature Reviews Materials, vol. 2, pp. 1-14, 2016.
[29] F. Lütolf, M. Stalder, and O. J. Martin, “Metallized Gratings Enable Color Effects and Floating Screen Films by First-Order Diffraction,” Advanced Optical Materials, vol. 3, pp. 1793-1799, 2015.
[30] A. B. Christiansen, E. Højlund-Nielsen, J. Clausen, G. P. Caringal, N. A. Mortensen, and A. Kristensen, “Imprinted and injection-molded nano-structured optical surfaces,” in Nanostructured Thin Films VI, 2013, p. 881803.
[31] H. D. Rowland, A. C. Sun, P. R. Schunk, and W. P. King, “Impact of polymer film thickness and cavity size on polymer flow during embossing: toward process design rules for nanoimprint lithography,” Journal of Micromechanics and Microengineering, vol. 15, p. 2414, 2005.
[32] J. Wang, P. Yi, Y. Deng, L. Peng, X. Lai, and J. Ni, “Recovery behavior of thermoplastic polymers in micro hot embossing process,” Journal of Materials Processing Technology, vol. 243, pp. 205-216, 2017
[33] R.-D. Chien, “Hot embossing of microfluidic platform,” International communications in heat and mass transfer, vol. 33, pp. 645-653, 2006.
[34] J. Li, C. Liu, and J. Peng, “Effect of hot embossing process parameters on polymer flow and microchannel accuracy produced without vacuum,” Journal of Materials Processing Technology, vol. 207, pp. 163-171, 2008.
[35] S. Lan, H.-J. Lee, E. Kim, J. Ni, S.-H. Lee, X. Lai, J.-H. Song, N. K. Lee, and M. G. Lee, “A parameter study on the micro hot-embossing process of glassy polymer for pattern replication,” Microelectronic Engineering, vol. 86, pp. 2369-2374, 2009.
[36] T. Glinsner, T. Veres, G. Kreindl, E. Roy, K. Morton, T. Wieser, C. Thanner, D. Treiblmayr, R. Miller, and P. Lindner, “Fully automated hot embossing processes utilizing high resolution working stamps,” Journal of Vacuum Science & Technology B, Nanotechnology and Microelectronics: Materials, Processing, Measurement, and Phenomena, vol. 28, pp. 36-41, 2010.
[37] L. Peng, Y. Deng, P. Yi, and X. Lai, “Micro hot embossing of thermoplastic polymers: a review,” Journal of Micromechanics and Microengineering, vol. 24, p. 013001, 2013.
[38] D. Dyer, S. Shreim, S. Jayadev, V. Lew, E. Botvinick, and M. Khine, “Sequential shrink photolithography for plastic microlens arrays,” Applied Physics Letters, vol. 99, p. 034102, 2011.
[39] C. M. Gabardo, Y. Zhu, L. Soleymani, and J. M. Moran-Mirabal, “Bench-top fabrication of hierarchically structured high-surface-area electrodes,” Advanced Functional Materials, vol. 23, pp. 3030-3039, 2013.
[40] E. Baquedano, R. V. Martinez, J. M. Llorens, and P. A. Postigo, “Fabrication of silicon nanobelts and nanopillars by soft lithography for hydrophobic and hydrophilic photonic surfaces,” Nanomaterials, vol. 7, p. 109, 2017.
[41] F. Laermer, S. Franssila, L. Sainiemi, and K. Kolari, “Deep reactive ion etching,” in Handbook of silicon based MEMS materials and technologies, ed: Elsevier, 2020, pp. 417-446.

While the applicant's teachings described herein are in conjunction with various embodiments for illustrative purposes, it is not intended that the applicant's teachings be limited to such embodiments as the embodiments described herein are intended to be examples. On the contrary, the applicant's teachings described and illustrated herein encompass various alternatives, modifications, and equivalents, without departing from the embodiments described herein, the general scope of which is defined in the appended claims.

1. A method of producing nanoscale features on a pre-stressed polymer film, the method comprising:
imprinting the pre-stressed polymer film with a nanoscale or microscale pattern;
constraining the pre-stressed polymer film in a first direction with a first constraint;
shrinking the pre-stressed polymer film in a second direction with a first heat treatment process;
releasing the first constraint;
constraining the pre-stressed polymer film in a third direction with a second constraint, the third direction being different than the first direction;
shrinking the pre-stressed polymer film in a fourth direction with a second heat treatment process; and
releasing the second constraint to produce the nanoscale features on the pre-stressed polymer film.

2. The method of claim 1, wherein a temperature of the first heat treatment process is controlled to achieve final shrink dimensions between 100% and 30% of original dimensions of the pre-stressed polymer film.

3. The method of claim 1, wherein the first heat treatment process is conducted at a first temperature and the second heat treatment process is conducted at a second temperature, the first temperature being different than the second temperature.

4. The method of claim 1, wherein the first constraint is mechanical clamp, adhesive bonding or an electromagnetic means.

5. The method of claim 1, wherein the pre-stressed polymer film is a thermoplastic material such as polystyrene, polypropylene, polyester, polycarbonate, or elastomeric material such as polydimethylsiloxane and polyurethane.

6. The method of claim 1, wherein a shrinkage gradient is achieved by controlling the placement of the first constraint or controlling a magnitude of the first constraint relative to a location of the pattern.

7. The method of claim 1, wherein the pre-stressed polymer film is imprinted at a temperature between 110° C. and 140° C. using a force in a range of about 1000 N to about 10,000 N.

8. The method of claim 1, wherein the first heat treatment process is performed for a first duration and the second heat treatment process is performed for a second duration.

9. The method of claim 1, wherein the first heat treatment process is applied to obtain partial shrinkage of the nanoscale or microscale pattern to achieve a tunable degree of miniaturization.

10. The method of claim 1, wherein the second direction is orthogonal to the first direction.

11. The method of claim 1, wherein the fourth direction is orthogonal to the third direction.

12. The method of claim 1, wherein the second direction and the third direction are a same direction.

13. The method of claim 1, wherein the third direction and the first direction differ by an angle, the angle being less than about 90 degrees.

14. The method of claim 1 further comprising
constraining the pre-stressed polymer film in a fifth direction with a third constraint;
shrinking the pre-stressed polymer film in a sixth direction with a third heat treatment process, the sixth direction being orthogonal to the fifth direction; and
releasing the third constraint to produce the nanoscale features on the pre-stressed polymer film.

15. The method of claim 1, wherein the imprinted pattern is a two-dimensional pattern.

16. The method of claim 1, wherein the imprinted pattern is a three-dimensional pattern.

17. The method of claim 1, wherein imprinting the prestressed polymer film includes imprinting the prestressed polymer film using xurography or laser machining lithography.

18. The method of claim 1, wherein the first constraint is a uniaxial constraint.

19. The method of claim 1, wherein the second constraint is a uniaxial constraint.

20. A method of producing nanoscale features on a pre-stressed polymer film, the method comprising iteratively repeating the method of claim 1.
